(19) United States
(12) Patent Application Publication
(10) Pub. No.: US 2025/0133955 A1
(43) Pub. Date: Apr. 24, 2025

(54) THERMALLY ACTIVATED DELAYED FLUORESCENCE (TADF) MATERIALS FOR HIGH EFFICIENCY ORGANIC PHOTOVOLTAICS

(71) Applicants: The Regents of the University of Michigan, Ann Arbor, MI (US); The University of Southern California, Los Angeles, CA (US)

(72) Inventors: Stephen R. Forrest, Ann Arbor, MI (US); Yongxi Li, Ann Arbor, MI (US); Chandler Dobson, Los Angeles, CA (US); Konstantin Mallon, Los Angeles, CA (US); Mark E. Thompson, Los Angeles, CA (US); Alex James Robb, Los Angeles, CA (US)

(21) Appl. No.: 18/914,827

(22) Filed: Oct. 14, 2024

Related U.S. Application Data
(60) Provisional application No. 63/667,363, filed on Jul. 3, 2024.
(60) Provisional application No. 63/592,252, filed on Oct. 23, 2023.

(51) Int. Cl. H10K 85/30; C09K 11/06; H10K 30/20; H10K 30/57; H10K 85/60; H10K 101/20

(52) U.S. Cl. CPC H10K 85/381; C09K 11/06; H10K 85/658; C09K 2211/1007; C09K 2211/1011; C09K 2211/1014; C09K 2211/1022; C09K 2211/1029; C09K 2211/1037; C09K 2211/1051; C09K 2211/188; H10K 30/20; H10K 30/57; H10K 2101/20

(57) ABSTRACT

Described are organic photovoltaic devices comprising an anode; a cathode; and a photoactive organic material in a layer disposed between the anode and the cathode, the energy difference between the triplet energy state (T₁) and the singlet energy state (S₁) (ΔE_{ST}) in the photoactive organic material is less than about 300 meV; and when the organic photovoltaic device is illuminated with light having an AM1.5 spectrum, the organic photovoltaic device has an open circuit voltage of greater than 0.9 V, a power conversion efficiency of greater than 22%, and an EL external quantum efficiency >5%.

### CROSS-REFERENCE TO RELATED APPLICATIONS

The present application claims priority to U.S. Provisional Application No. 63/667,363, filed Jul. 3, 2024, and U.S. Provisional Application No. 63/592,252, filed Oct. 23, 2023, each of which is incorporated by reference herein in its entirety.

### STATEMENT REGARDING FEDERALLY SPONSORED RESEARCH OR DEVELOPMENT

This invention was made with government support under DE-EE0008561 awarded by the U.S. Department of Energy. The government has certain rights in the invention.

### FIELD

The present disclosure generally relates to electrically active, optically active, solar, and semiconductor devices, and in particular, to organic photovoltaic cells and compositions in such organic photovoltaic cells.

### BACKGROUND

Optoelectronic devices rely on the optical and electronic properties of materials to either produce or detect electromagnetic radiation electronically or to generate electricity from ambient electromagnetic radiation.

Photosensitive optoelectronic devices convert electromagnetic radiation into electricity. Solar cells, also called photovoltaic (PV) devices or cells, are a type of photosensitive optoelectronic device that is specifically used to generate electrical power. PV devices, which may generate electrical energy from light sources other than sunlight, may be used to drive power consuming loads to provide, for example, lighting, heating, or to power electronic circuitry or devices such as calculators, radios, computers or remote monitoring or communications equipment. These power generation applications may involve the charging of batteries or other energy storage devices so that operation may continue when direct illumination from the sun or other light sources is not available, or to balance the power output of the PV device with the specific applications requirements.

Traditionally, photosensitive optoelectronic devices have been constructed of a number of inorganic semiconductors, e.g., crystalline, polycrystalline and amorphous silicon, gallium arsenide, cadmium telluride, and others.

More recent efforts have focused on the use of organic photovoltaic (OPV) cells to achieve acceptable photovoltaic conversion efficiencies with economical production costs. OPVs offer a low-cost, light-weight, and mechanically flexible route to solar energy conversion. Compared with polymers, small molecule OPVs share the advantage of using materials with well-defined molecular structures and weights. This leads to a reliable pathway for purification and the ability to deposit multiple layers using highly controlled thermal deposition without concern for dissolving, and thus damaging, previously deposited layers or subcells.

In addition to the pursuit of high device efficiency, OPVs have unique advantages, such as the application of semi-transparent solar cells for use in building integrated photovoltaics (BIPV). Considering the vast surface areas of windows and facades in modern urban environments, developing semi-transparent solar cells with both high efficiency and transmittance has become increasingly important. For a solar cell to be highly transparent, visible light would have to travel uninhibited to the eye, and hence cannot be absorbed. Selectively harvesting near-infrared (NIR) radiation avoids competition between efficiency and transmittance. However, the lack of high performance NIR absorbers in conventional fullerene based OPVs has prevented the attainment of efficient, yet highly transparent (in the visible) devices. To date, semi-transparent OPVs based on fullerene acceptors show only PCE less than or equal to 4% with average visible transmittance of 61%.

### SUMMARY OF THE DISCLOSURE

In one aspect, the present disclosure relates to an organic photovoltaic device comprising:
an anode;
a cathode; and
a photoactive organic material in a layer disposed between the anode and the cathode,
wherein:
   the energy difference between the triplet energy state (T₁) and the singlet energy state (S₁) (ΔE_{ST}) in the photoactive organic material is less than about 300 meV; and
   when the organic photovoltaic device is illuminated with light having an AM1.5 spectrum, the organic photovoltaic device has an open circuit voltage of greater than 0.9 V and a power conversion efficiency of greater than 22%, and an EL external quantum efficiency >5%.

### BRIEF DESCRIPTION OF THE DRAWINGS

For a more complete understanding of the disclosure, reference is made to the following detailed description and accompanying drawing figures, in which like reference numerals may be used to identify like elements in the figures.

FIG. 1 depicts exemplary organophotovoltaic device 100.

FIG. 2 depicts exemplary organophotovoltaic device 200.

FIG. 3 depicts a plot showing the charge separation and recombination process of conventional OPV cells. ΔE₁ is the thermalization loss, ΔE₂ is the exciton dissociation loss, and ΔE₃ is the radiative and non-radiative recombination loss.

FIG. 4 is a comparison between state-of-the-art organic solar cells with inorganic technology. Voltage loss is the limiting factor in OPV achieving efficiencies.

FIG. 5 depicts a state-of-the-art stable NFA-based OPV with ultrathin (2 nm) C₇₀ and monolayer IC-SAM interface buffers.

FIG. 6 depicts exemplary self-assembled anode and cathode buffer layer materials.

FIG. 7 is a plot of extrapolated degradation of a population of NFA-based OPVs under 1-27 sun ALT conditions. T₈₀ is the time for the efficiency to drop to 80% of its initial value. In this case its extrapolated value under 1 sun illumination is 30 yr.

FIG. 8 is a schematic structure of a 15% efficient organic tandem cell.

FIG. 9 is an optical model of the absorption of an AM1.5G reference spectrum. The dashed red line indicates the charge recombination zone connecting the top and bottom cells.

FIG. 10 is a series of plots showing the performance of the tandem cell depicted in FIG. 8.

FIG. 11 is a depiction of how the 2,2′-dipyrromethene structural feature is present in molecules of interest. Synthetic ease increases as structural complexity is reduced from a bridged dipyrrin down to a BODIPY.

FIG. 12 is a depiction of the donor groups, acceptor groups, and alkyl chains of the compound Y6.

### DETAILED DESCRIPTION

The present disclosure provides non-fullerene acceptors (NFAs) with good photostability and morphological stability. In some aspects, employing these NFAs in the one or more device architectures, OPV device is achieved with improved the operational lifetime.

Various non-limiting examples of OPVs and compositions within various layers of an OPV are described in greater detail below.

### Definitions

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, the terms “electrode” and “contact” may refer to a layer that provides a medium for delivering current to an external circuit or providing a bias current or voltage to the device. For example, an electrode, or contact, may provide the interface between the active regions of an organic photosensitive optoelectronic device and a wire, lead, trace or other means for transporting the charge carriers to or from the external circuit. Examples of electrodes include anodes and cathodes, which may be used in a photosensitive optoelectronic device.

As used herein, the term “transparent” may refer to a material that permits at least 50% of the incident electromagnetic radiation in relevant wavelengths to be transmitted through it. In a photosensitive optoelectronic device, it may be desirable to allow the maximum amount of ambient electromagnetic radiation from the device exterior to be admitted to the photoconductive active interior region. That is, the electromagnetic radiation must reach a photoconductive layer(s), where it can be converted to electricity by photoconductive absorption. This often dictates that at least one of the electrical contacts or electrodes should be minimally absorbing and minimally reflecting of the incident electromagnetic radiation. In some cases, such a contact should be transparent or at least semi-transparent. In one embodiment, the transparent material may form at least part of an electrical contact or electrode.

As used herein, the term “semi-transparent” may refer to a material that permits some, but less than 50% transmission of ambient electromagnetic radiation in relevant wavelengths. Where a transparent or semi-transparent electrode is used, the opposing electrode may be a reflective material so that light which has passed through the cell without being absorbed is reflected back through the cell.

As used and depicted herein, a “layer” refers to a member or component of a device, for example an optoelectronic device, being principally defined by a thickness, for example in relation to other neighboring layers, and extending outward in length and width. It should be understood that the term “layer” is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the length and width may be disturbed or otherwise interrupted by other layer(s) or material(s).

As used herein, a “photoactive region” refers to a region of a device that absorbs electromagnetic radiation to generate excitons. Similarly, a layer is “photoactive” if it absorbs electromagnetic radiation to generate excitons. The excitons may dissociate into an electron and a hole in order to generate an electrical current.

As used herein, the terms “donor” and “acceptor” refer to the relative positions of the highest occupied molecular orbital (“HOMO”) and lowest unoccupied molecular orbital (“LUMO”) energy levels of two contacting but different organic materials. If the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

As used herein, the term “band gap” (E_{g}) of a polymer may refer to the energy difference between the HOMO and the LUMO. The band gap is typically reported in electron volts (eV). The band gap may be measured from the UV-vis spectroscopy or cyclic voltammetry. A “low band gap” polymer may refer to a polymer with a band gap below 2 eV, e.g., the polymer absorbs light with wavelengths longer than 620 nm.

As used herein, the term “excitation binding energy” (E_{B}) may refer to the following formula: E_{B}=(M⁺+M⁻)−(M*+M), where M⁺ and M⁻ are the total energy of a positively and negatively charged molecule, respectively; M* and M are the molecular energy at the first singlet state (S₁) and ground state, respectively. Excitation binding energy of acceptor or donor molecules affects the energy offset needed for efficient exciton dissociation. In certain examples, the escape yield of a hole increases as the HOMO offset increases. A decrease of exciton binding energy Ep for the acceptor molecule leads to an increase of hole escape yield for the same HOMO offset between donor and acceptor molecules.

As used herein, “power conversion efficiency” (PCE) (nₚ) may be expressed as:

$${η}_{ρ} = \frac{{V}_{OC} * FF * {J}_{SC}}{{P}_{O}}$$

wherein V_{OC} is the open circuit voltage, FF is the fill factor, J_{SC} is the short circuit current, and P_{O} is the input optical power.

As used herein, “spin coating” may refer to the process of solution depositing a layer or film of one material (i.e., the coating material) on a surface of an adjacent substrate or layer of material. The spin coating process may include applying a small amount of the coating material on the center of the substrate, which is either spinning at low speed or not spinning at all. The substrate is then rotated at high speed in order to spread the coating material by centrifugal force. Rotation is continued while the fluid spins off the edges of the substrate, until the desired thickness of the film is achieved. The applied solvent is usually volatile, and simultaneously evaporates. Therefore, the higher the angular speed of spinning, the thinner the film. The thickness of the film also depends on the viscosity and concentration of the solution and the solvent.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Details on OLEDs, and the definitions described above, can be found in U.S. Pat. No. 7,279,704, which is incorporated herein by reference in its entirety.

The terms “halo,” “halogen,” and “halide” are used interchangeably and refer to fluorine, chlorine, bromine, and iodine.

The term “pseudohalogen” refers to polyatomic analogues of halogens, whose chemistry, resembling that of the true halogens, allows them to substitute for halogens in several classes of chemical compounds. Exemplary pseudohalogens include, but are not limited to, nitrile, cyaphide, isocyanide, cyanate, isocyanate, fulminate, thiocyanate, isothiocyanate, selenocyanate, tellurocyanate, azide, tetracarbonylcobaltate, trinitromethanide, and tricyanomethanide groups.

The term “acyl” refers to a substituted carbonyl radical (C(O)—Rₛ).

The term “ester” refers to a substituted oxycarbonyl (—O—C(O)—Rₛ or —C(O)—O—Rₛ) radical.

The term “ether” refers to an —ORₛ radical.

The terms “sulfanyl” or “thio-ether” are used interchangeably and refer to a —SRₛ radical.

The term “sulfinyl” refers to a —S(O)—Rₛ radical.

The term “sulfonyl” refers to a —SO₂—Rₛ radical.

The term “phosphino” refers to a —P(Rₛ)₃ radical, wherein each Rₛ can be same or different.

The term “silyl” refers to a —Si(Rₛ)₃ radical, wherein each Rₛ can be same or different.

The term “boryl” refers to a —B(Rₛ)₂ radical or its Lewis adduct —B(Rs)3 radical, wherein Rs can be same or different.

In each of the above, Rs can be hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. Preferred Rs is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group is optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group is optionally substituted.

The terms “heteroalkyl” or “heterocycloalkyl” refer to an alkyl or a cycloalkyl radical, respectively, having at least one carbon atom replaced by a heteroatom. Optionally the at least one heteroatom is selected from O, S, N, P, B, Si and Se, preferably, O, S or N. Additionally, the heteroalkyl or heterocycloalkyl group is optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group is optionally substituted.

The term “alkynyl” refers to and includes both straight and branched chain alkyne radicals. Preferred alkynyl groups are those containing two to fifteen carbon atoms. Additionally, the alkynyl group is optionally substituted.

The terms “aralkyl” or “arylalkyl” are used interchangeably and refer to an alkyl group that is substituted with an aryl group. Additionally, the aralkyl group is optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group is optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group is optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more general substituents.

In many instances, the general substituents are selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof.

In some instances, the preferred general substituents are selected from the group consisting of deuterium, fluorine, alkyl, cycloalkyl, heteroalkyl, alkoxy, aryloxy, amino, silyl, alkenyl, cycloalkenyl, heteroalkenyl, aryl, heteroaryl, nitrile, isonitrile, sulfanyl, and combinations thereof.

In some instances, the preferred general substituents are selected from the group consisting of deuterium, fluorine, alkyl, cycloalkyl, alkoxy, aryloxy, amino, silyl, aryl, heteroaryl, sulfanyl, and combinations thereof.

In yet other instances, the more preferred general substituents are selected from the group consisting of deuterium, fluorine, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents no substitution, R¹, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and organic vapor jet printing (OVJP). Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components.

The materials and structures described herein may have applications in devices other than organic solar cells. For example, other optoelectronic devices such as organic electroluminescent devices (OLEDs) and organic photodetectors may employ the materials and structures. More generally, organic devices, such as organic transistors, may employ the materials and structures.

### Organic Photovoltaic Cells

In one aspect, the disclosure relates to an OPV device comprising a compound disclosed herein. In one embodiment, the OPV device includes an anode; a cathode; and an active material positioned between the anode and cathode. In one embodiment, the active material comprises an acceptor and a donor.

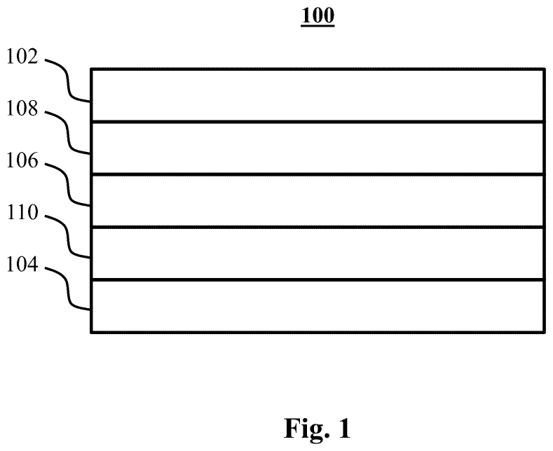

In one embodiment, the OPV device comprises a single-junction organic photovoltaic device 100 having a non-fullerene acceptor compound (FIG. 1). In one embodiment, the OPV device comprises two electrodes having an anode 102 and a cathode 104 in superposed relation, at least one donor composition, and at least one acceptor composition, wherein the donor-acceptor material or active layer 106 is positioned between the two electrodes 102 and 104. In one embodiment, one or more intermediate layers 108 may be positioned between the anode 102 and the active layer 106. Additionally, or alternatively, one or more intermediate layers 110 may be positioned between the active layer 106 and cathode 104.

In one embodiment, the anode 102 comprises a conducting oxide, thin metal layer, or conducting polymer. In one embodiment, the anode 102 comprises a conductive metal oxide. Exemplary conductive metal oxides include, but are not limited to, indium tin oxide (ITO), tin oxide (TO), gallium indium tin oxide (GITO), zinc oxide (ZO), and zinc indium tin oxide (ZITO). In one embodiment, the anode 102 comprises a metal layer. Exemplary metals for the metal layer include, but are not limited to, Ag, Au, Pd, Pt, Ti, V, Zn, Sn, Al, Co, Ni, Cu, Cr, and combinations thereof. In one embodiment, the metal layer comprises a thin metal layer. In one embodiment, the anode 102 comprises a conductive polymer. Exemplary conductive polymers include, but are not limited to, polyanaline (PANI), or 3,4-polyethylenedioxythiophene:polystyrenesulfonate (PEDOT:PSS). In one embodiment, thickness of the anode 102 is between about 0.1-100 nm. In one embodiment, thickness of the anode 102 is between about 1-10 nm. In one embodiment, thickness of the anode 102 is between about 0.1-10 nm. In one embodiment, thickness of the anode 102 is between about 10-100 nm. In one embodiment, anode 102 comprises a transparent or semi-transparent conductive material.

In one embodiment, the cathode 104 comprises a conducting oxide, a metal layer, or conducting polymer. Exemplary conducting oxide, metal layers, and conducting polymers are described elsewhere herein. In one embodiment, the cathode comprises a thin metal layer. In one embodiment, the cathode 104 comprises a metal or metal alloy. In one embodiment, the cathode 104 may comprise Ca, Al, Mg, Ti, W, Ag, Au, or another appropriate metal, or an alloy thereof. In one embodiment, the thickness of the cathode 104 is between about 0.1-100 nm. In one embodiment, the thickness of the cathode 104 is between about 1-10 nm. In one embodiment, the thickness of the cathode 104 is between about 0.1-10 nm. In one embodiment, the thickness of the cathode 104 is between about 10-100 nm. In one embodiment, cathode 104 comprises a transparent or semi-transparent conductive material.

In one embodiment, the OPV device may comprise one or more charge collecting/transporting intermediate layers positioned between an electrode 102, 104, and the active region or layer 106. In one embodiment, the OPV device comprises intermediate layer 108. In one embodiment, the OPV device comprises intermediate layer 110. In one embodiment, the OPV device comprises both intermediate layers 108 and 110. In one embodiment, intermediate layer 108 comprises a metal oxide. In one embodiment, intermediate layer 110 comprises a metal oxide. Exemplary metal oxides include, but are not limited to, MoO3, V2O5, ZnO, and TiO2. In one embodiment, the first intermediate layer 108 has the same composition as the second intermediate layer 110. In one embodiment, the first intermediate layer 108 and the second intermediate layer 110 have different compositions. In one embodiment, the thickness of intermediate layer 108 and intermediate layer 110 are each independently between about 0.1-100 nm. In one embodiment, the thickness of intermediate layer 108 and intermediate layer 110 are each independently between about 1-10 nm. In one embodiment, the thickness of intermediate layer 108 and intermediate layer 110 are each independently between about 0.1-10 nm. In one embodiment, the thickness of intermediate layer 108 and intermediate layer 110 are each independently between about 10-100 nm.

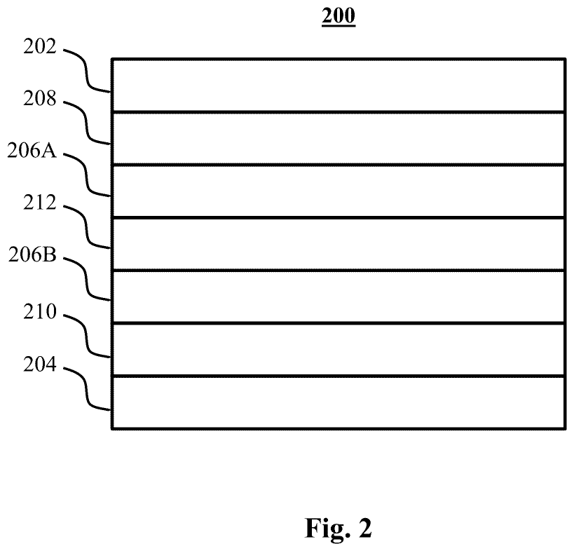

In one embodiment, the OPV device comprises various layers of a tandem or multi-junction photovoltaic device 200 having a non-fullerene acceptor compound (FIG. 2). In one embodiment, the OPV device comprises two electrodes having an anode 202 and a cathode 204 in superposed relation, at least one donor composition, and at least one acceptor composition positioned within a plurality of active layers or regions 206A and 206B between the two electrodes 202 and 204. Additional active layers or regions are also possible. In one embodiment, the anode 202 and the cathode 204 each independently comprise a conducting oxide, thin metal layer, or conducting polymer. Exemplary conducting oxides, metal layers, and conducting polymers are described elsewhere herein.

In one embodiment, the OPV device comprises one or more intermediate layers 208 positioned between the anode 202 and a first active layer 206A. Additionally, or alternatively, at least one intermediate layer 210 may be positioned between the second active layer 206B and cathode 204. In one embodiment, the OPV device comprises one or more intermediate layers 212 positioned between the first active layer 206A and the second active layer 206B. In one embodiment, the OPV device comprises intermediate layer 208. In one embodiment, the OPV device comprises intermediate layer 210. In one embodiment, the OPV device comprises intermediated layer 212. In one embodiment, the OPV device comprises both intermediate layers 208 and 210. In one embodiment, the OPV device comprises both intermediate layers 208 and 212. In one embodiment, the OPV device comprises both intermediate layers 210 and 212. In one embodiment, the OPV device comprises intermediate layers 208, 210, and 212. In one embodiment, intermediate layer 208 comprises a metal oxide. In one embodiment, intermediate layer 210 comprises a metal oxide. In one embodiment, intermediate layer 212 comprises a metal oxide. Exemplary metal oxides are described elsewhere herein. Exemplary thicknesses for intermediate layers 208, 210, and 212 are described elsewhere herein.

According to one aspect, the present disclosure relates to an organic photovoltaic device comprising:
an anode;
a cathode; and
a photoactive organic material in a layer disposed between the anode and the cathode,
wherein:
   the energy difference between the triplet energy state (T₁) and the singlet energy state (S₁) (ΔE_{ST}) in the photoactive organic material is less than about 300 meV; and
   when the organic photovoltaic device is illuminated with light having an AM1.5 spectrum, the organic photovoltaic device has an open circuit voltage of greater than 0.9 V, a power conversion efficiency of greater than 22%, and an EL external quantum efficiency >5%.

In one embodiment, the energy difference between the triplet energy state (T₁) and the singlet energy state (S₁) (ΔE_{ST}) is less than about 100 meV. In one embodiment, the ΔE_{ST} is less than about 150 meV. In one embodiment, the ΔE_{ST} is less than about 200 meV. In one embodiment, the ΔE_{ST} is less than about 250 meV. In one embodiment, the ΔE_{ST} is less than about 300 meV. In one embodiment, the ΔE_{ST} is less than about 350 meV. In one embodiment, the ΔE_{ST} is less than about 400 meV. In one embodiment, the ΔE_{ST} is less than about 450 meV. In one embodiment, the ΔE_{ST} is less than about 500 meV.

In one embodiment, the organic photovoltaic device has an open circuit voltage of greater than 0.9 V when illuminated with light. In one embodiment, the organic photovoltaic device has an open circuit voltage of greater than about 0.5 V when illuminated with light. In one embodiment, the organic photovoltaic device has an open circuit voltage of greater than about 0.6 V when illuminated with light. In one embodiment, the organic photovoltaic device has an open circuit voltage of greater than about 0.7 V when illuminated with light. In one embodiment, the organic photovoltaic device has an open circuit voltage of greater than about 0.8 V when illuminated with light. In one embodiment, the organic photovoltaic device has an open circuit voltage of greater than about 0.9 V when illuminated with light. In one embodiment, the organic photovoltaic device has an open circuit voltage of greater than about 1.0 V when illuminated with light.

In one embodiment, the organic photovoltaic device has an open circuit voltage of greater than 0.9 V when illuminated with light having an AM1.5 spectrum. In one embodiment, the organic photovoltaic device has an open circuit voltage of greater than about 0.5 V when illuminated with light having an AM1.5 spectrum. In one embodiment, the organic photovoltaic device has an open circuit voltage of greater than about 0.6 V when illuminated with light having an AM1.5 spectrum. In one embodiment, the organic photovoltaic device has an open circuit voltage of greater than about 0.7 V when illuminated with light having an AM1.5 spectrum. In one embodiment, the organic photovoltaic device has an open circuit voltage of greater than about 0.8 V when illuminated with light having an AM1.5 spectrum. In one embodiment, the organic photovoltaic device has an open circuit voltage of greater than about 0.9 V when illuminated with light having an AM1.5 spectrum. In one embodiment, the organic photovoltaic device has an open circuit voltage of greater than about 1.0 V when illuminated with light having an AM1.5 spectrum.

In one embodiment, the power conversion efficiency of the device is greater than 22% when illuminated with light. In one embodiment, the power conversion efficiency of the device is greater than about 5% when illuminated with light. In one embodiment, the power conversion efficiency of the device is greater than about 10% when illuminated with light. In one embodiment, the power conversion efficiency of the device is greater than about 15% when illuminated with light. In one embodiment, the power conversion efficiency of the device is greater than about 20% when illuminated with light. In one embodiment, the power conversion efficiency of the device is greater than about 25% when illuminated with light.

In one embodiment, the power conversion efficiency of the device is greater than 22% when illuminated with light having an AM1.5 spectrum. In one embodiment, the power conversion efficiency of the device is greater than about 5% when illuminated with light having an AM1.5 spectrum. In one embodiment, the power conversion efficiency of the device is greater than about 10% when illuminated with light having an AM1.5 spectrum. In one embodiment, the power conversion efficiency of the device is greater than about 15% when illuminated with light having an AM1.5 spectrum. In one embodiment, the power conversion efficiency of the device is greater than about 20% when illuminated with light having an AM1.5 spectrum. In one embodiment, the power conversion efficiency of the device is greater than about 25% when illuminated with light having an AM1.5 spectrum.

In one embodiment, organic photovoltaic device has an EL external quantum efficiency ≥5%. In one embodiment, organic photovoltaic device has an EL external quantum efficiency ≥7.5%. In one embodiment, organic photovoltaic device has an EL external quantum efficiency ≥10%. In one embodiment, organic photovoltaic device has an EL external quantum efficiency ≥12.5%. In one embodiment, organic photovoltaic device has an EL external quantum efficiency ≥15%. In one embodiment, organic photovoltaic device has an EL external quantum efficiency ≥17.5%. In one embodiment, organic photovoltaic device has an EL external quantum efficiency ≥20%. In one embodiment, organic photovoltaic device has an EL external quantum efficiency ≥22.5%. In one embodiment, organic photovoltaic device has an EL external quantum efficiency ≥25%. In one embodiment, organic photovoltaic device has an EL external quantum efficiency ≥27.5%. In one embodiment, organic photovoltaic device has an EL external quantum efficiency ≥30%. In one embodiment, organic photovoltaic device has an EL external quantum efficiency ≥32.5%. In one embodiment, organic photovoltaic device has an EL external quantum efficiency ≥35%. In one embodiment, organic photovoltaic device has an EL external quantum efficiency ≥37.5%. In one embodiment, organic photovoltaic device has an EL external quantum efficiency ≥40%. In one embodiment, organic photovoltaic device has an EL external quantum efficiency ≥42.5%. In one embodiment, organic photovoltaic device has an EL external quantum efficiency ≥45%. In one embodiment, organic photovoltaic device has an EL external quantum efficiency ≥ 47.5%. In one embodiment, organic photovoltaic device has an EL external quantum efficiency ≥50%.

In one embodiment, the organic photovoltaic device is a tandem photovoltaic device. In one embodiment, the organic photovoltaic device is a tandem photovoltaic device comprising at least two subcells. In one embodiment, the organic photovoltaic device is a tandem photovoltaic device comprising at least two subcells, wherein at least one subcell is organic, and at least one subcell is organic, perovskite, or CdTe. In one embodiment, the subcells are monolithically integrated. In one embodiment, at least one subcell comprises an electrically conductive material. In one embodiment, at least one subcell comprises a perovskite. In one embodiment, at least one subcell comprises cadmium telluride (CdTe). In one embodiment, at least one subcell comprises a metal.

In one embodiment, the present invention relates to an organic photovoltaic device comprising: an anode; a cathode; and an organic layer disposed between the anode and the cathode, comprising a compound of General Formula (I):

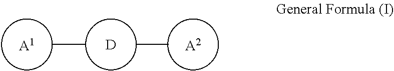

wherein:
D is a donor; and
A¹ and A² are each independently an acceptor;
wherein the energy difference between the triplet energy state (T₁) and the singlet energy state (S₁) (ΔE_{ST}) is less than about 200 meV.

In one embodiment, the oscillator strength for the transition from the ground state and the lowest energy excited state is at least 0.1. In one embodiment, the oscillator strength for the transition from the ground state and the lowest energy excited state is less than 0.1. In one embodiment, the oscillator strength for the transition from the ground state and the lowest energy excited state is about 0.2. In one embodiment, the oscillator strength for the transition from the ground state and the lowest energy excited state is about 0.3. In one embodiment, the oscillator strength for the transition from the ground state and the lowest energy excited state is about 0.4. In one embodiment, the oscillator strength for the transition from the ground state and the lowest energy excited state is about 0.5. In one embodiment, the oscillator strength for the transition from the ground state and the lowest energy excited state is greater than 0.1.

In one embodiment, the compound has a HOMO/LUMO overlap of greater than 10%. In one embodiment, the compound has a HOMO/LUMO overlap of greater than about 5%. In one embodiment, the compound has a HOMO/LUMO overlap of greater than about 10%. In one embodiment, the compound has a HOMO/LUMO overlap of greater than 15%.

In one embodiment, the organic photovoltaic device further comprises a compound comprising one of the following general formulae:

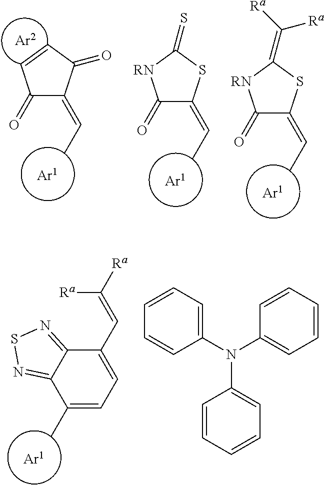

wherein
Ar¹ and Ar² are each independently selected from C₅-C₁₆ aryl and C₂-C₁₆ heteroaryl; and
R^{a} is an electron withdrawing group.

In one embodiment, the present invention relates to an organic photovoltaic device comprising an anode; a cathode; and an organic layer disposed between the anode and the cathode, comprising a compound of General Formula (I):

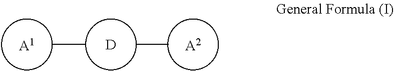

wherein:
D is a donor;
A¹ and A² are each independently a compound capable of thermally assisted delayed fluorescence (TADF); and
A¹ and A² are each covalently bound to D.

In one embodiment, the present invention further relates to an organic photovoltaic device comprising: an anode; a cathode; and an organic layer disposed between the anode and the cathode, comprising a compound of General Formula (I):

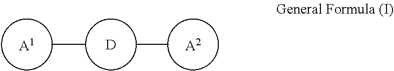

wherein:
D is a donor;
A¹ and A² are each independently an acceptor; and
D is a compound capable of thermally assisted delayed fluorescence (TADF).

In one embodiment, the present invention further relates to an organic photovoltaic device comprising: an anode; a cathode; and an organic layer disposed between the anode and the cathode, comprising a compound of General Formula (I):

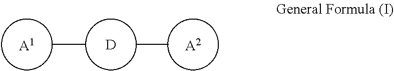

wherein:
D is a donor;
A¹ and A² are each independently an acceptor; and
the oscillator strength for the transition from the ground state and the lowest energy excited state is at least 0.1.

In one embodiment, the present invention further relates to an organic photovoltaic device comprising: an anode; a cathode; at least one anode buffer or at least one cathode buffer; and an organic layer disposed between the anode and the cathode, comprising a compound of General Formula (I):

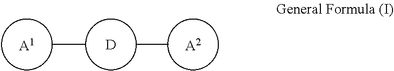

wherein:
D is a donor;
A¹ and A² are each independently an acceptor; and
the energy difference between the triplet energy state (T₁) and the singlet energy state (S₁) (ΔE_{ST}) is less than about 200 meV.

In one embodiment, the OPV device comprises a single-junction organic photovoltaic device. In one embodiment, the OPV device comprises two electrodes having an anode and a cathode in superposed relation, at least one donor composition, and at least one acceptor composition, wherein the donor-acceptor material or active layer is positioned between the two electrodes. In one embodiment, one or more intermediate layers may be positioned between the anode and the active layer. Additionally, or alternatively, one or more intermediate layers may be positioned between the active layer and cathode.

In one embodiment, the anode comprises a conducting oxide, thin metal layer, or conducting polymer. In one embodiment, the anode comprises a conductive metal oxide. Exemplary conductive metal oxides include, but are not limited to, indium tin oxide (ITO), tin oxide (TO), gallium indium tin oxide (GITO), zinc oxide (ZO), and zinc indium tin oxide (ZITO). In one embodiment, the anode comprises a metal layer. Exemplary metals for the metal layer include, but are not limited to, Ag, Au, Pd, Pt, Ti, V, Zn, Sn, Al, Co, Ni, Cu, Cr, and combinations thereof. In one embodiment, the metal layer comprises a thin metal layer. In one embodiment, the anode 102 comprises a conductive polymer. Exemplary conductive polymers include, but are not limited to, polyanaline (PANI), or 3,4-polyethylenedioxythiophene:polystyrenesulfonate (PEDOT:PSS). In one embodiment, thickness of the anode is between about 0.1-100 nm. In one embodiment, thickness of the anode is between about 1-10 nm. In one embodiment, thickness of the anode is between about 0.1-10 nm. In one embodiment, thickness of the anode is between about 10-100 nm. In one embodiment, anode comprises a transparent or semi-transparent conductive material.

In one embodiment, the cathode comprises a conducting oxide, a metal layer, or conducting polymer. Exemplary conducting oxide, metal layers, and conducting polymers are described elsewhere herein. In one embodiment, the cathode comprises a thin metal layer. In one embodiment, the cathode comprises a metal or metal alloy. In one embodiment, the cathode may comprise Ca, Al, Mg, Ti, W, Ag, Au, or another appropriate metal, or an alloy thereof. In one embodiment, the thickness of the cathode is between about 0.1-100 nm. In one embodiment, the thickness of the cathode is between about 1-10 nm. In one embodiment, the thickness of the cathode is between about 0.1-10 nm. In one embodiment, the thickness of the cathode is between about 10-100 nm. In one embodiment, cathode comprises a transparent or semi-transparent conductive material.

In one embodiment, the OPV device may comprise one or more charge collecting/transporting intermediate layers positioned between an electrode and the active region or layer. In one embodiment, the OPV device comprises one or more intermediate layers. In one embodiment, the intermediate layer comprises a metal oxide. Exemplary metal oxides include, but are not limited to, MoO3, MoOₓ, V₂O₅, ZnO, and TiO₂. In one embodiment, the first intermediate layer has the same composition as the second intermediate layer. In one embodiment, the first intermediate layer and the second intermediate layer have different compositions. In one embodiment, the thickness of the intermediate layers are each independently between about 0.1-100 nm. In one embodiment, the thickness of the intermediate layers are each independently between about 1-10 nm. In one embodiment, the thickness of the intermediate layers are each independently between about 0.1-10 nm. In one embodiment, the thickness of the intermediate layers are each independently between about 10-100 nm.

In one embodiment, the OPV device comprises various layers of a tandem or multi-junction photovoltaic device. In one embodiment, the OPV device comprises two electrodes having an anode and a 204 in superposed relation, at least one donor composition, and at least one acceptor composition positioned within a plurality of active layers or regions between the two electrodes. Additional active layers or regions are also possible. In one embodiment, the anode and the cathode each independently comprise a conducting oxide, thin metal layer, or conducting polymer. Exemplary conducting oxides, metal layers, and conducting polymers are described elsewhere herein.

In one embodiment, the OPV device comprises one or more intermediate layers positioned between the anode and a first active layer. Additionally, or alternatively, at least one intermediate layer may be positioned between the second active layer and cathode. In one embodiment, the OPV device comprises one or more intermediate layers positioned between the first active layer and the second active layer. In one embodiment, the OPV device comprises a first intermediate layer. In one embodiment, the OPV device comprises a second intermediate layer. In one embodiment, the OPV device comprises a third intermediate layer. In one embodiment, the OPV device comprises both first and second intermediate layers. In one embodiment, the OPV device comprises both first and third intermediate layers. In one embodiment, the OPV device comprises both second and third intermediate layers. In one embodiment, the OPV device comprises first, second, and third intermediate layers. In one embodiment, the first, second, and/or third intermediate layer comprises a metal oxide. Exemplary metal oxides are described elsewhere herein.

### Compounds

In one embodiment, the present invention further relates to a compound represented by General Formula (I):

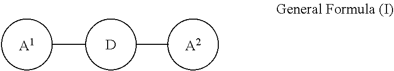

wherein:
D is a donor; and
A¹ and A² are each independently an acceptor; and
the energy difference between the triplet energy state (T₁) and the singlet energy state (S₁) (ΔE_{ST}) is less than about 200 meV.

In one embodiment, D comprises a group represented by a formula selected from the group consisting of Formula (D-1) to Formula (D-5):

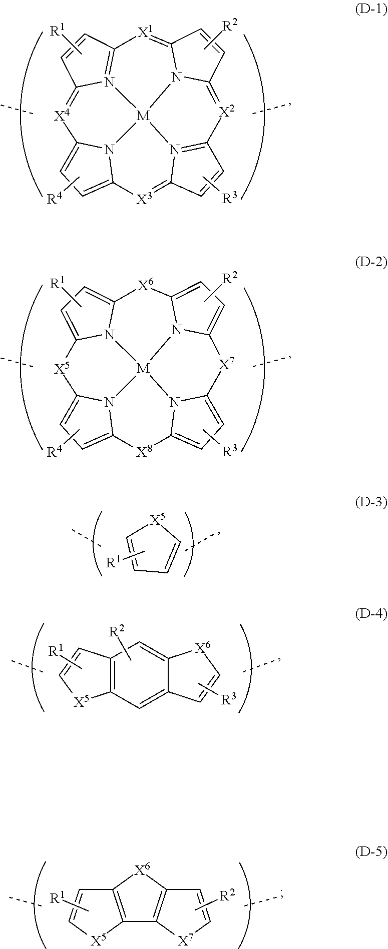

wherein
the dashed lines indicate direct bonds to A¹ and A²;
M is a monovalent, divalent, trivalent, or tetravalent atom;
each R¹ to R⁴ independently represents mono to the maximum allowable substitution;
each R¹ to R⁴ independently represents hydrogen or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof;
any two adjacent R¹ to R⁴ are optionally joined or fused together to form a ring which is optionally substituted;
each X¹ to X⁴ independently represents CR or N;
each X⁵ to X⁷ independently represents CR₂, NR, O, or S; and
each R is independently an electron donating group, hydrogen, or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof.

In one embodiment, D comprises a structure selected from the group consisting of:

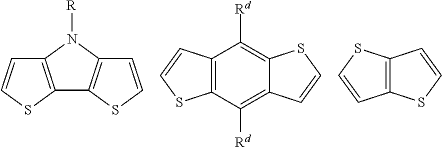

wherein
R is selected from the group consisting of an electron donating group, hydrogen, or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof; and
each R^{d} is independently an electron donating group.

In one embodiment, D comprises a structure represented by Formula (D-6):

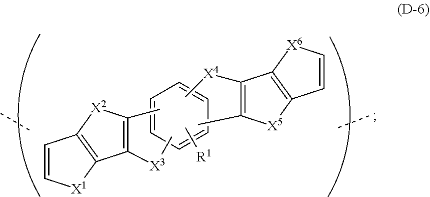

wherein
the dashed lines indicate direct bonds to A¹ and A²;
each X¹ to X⁴ independently represents O, S, NR, and CR₂;
R¹ represents mono to the maximum allowable substitution;
each R is independently hydrogen or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof; and
each occurrence of R¹ is independently selected from the group consisting of an electron donating group, hydrogen, or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof.

In one embodiment, D is represented by a structure selected from the group consisting of:

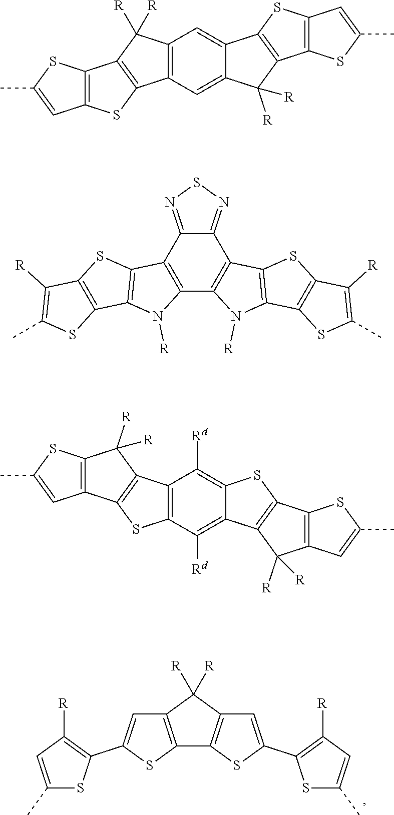

wherein
each R independently represents hydrogen or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof;
each R^{d} independently represents an electron donating group; and
the dashed lines indicate direct bonds to A¹ and A².

In one embodiment, R^{d} is selected from the group consisting of C₅-C₁₆ aryl, C₂-C₁₆ heteroaryl, C₅-C₂₀ alkoxy, and NR₂.

In one embodiment, A¹ and A² each independently comprise a group represented by a formula selected from the group consisting of Formula (A-1) to Formula (A-7):

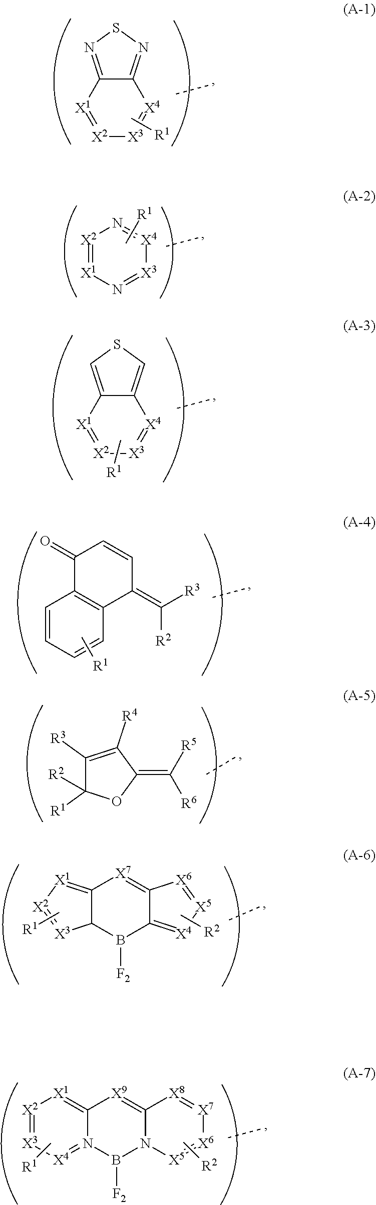

wherein
the dashed line indicates the direct bond to D;
each R¹ to R⁶ independently represents mono to the maximum allowable substitution;
each R¹ to R⁶ independently represents hydrogen or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof;
wherein any two adjacent R¹ to R⁶ are optionally joined or fused together to form a ring which is optionally substituted;
each X¹ to X⁹ independently represents CR or N; and
each R is independently an electron withdrawing group, hydrogen, or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof.

In one embodiment, A¹ and A² are each independently selected from the group consisting of

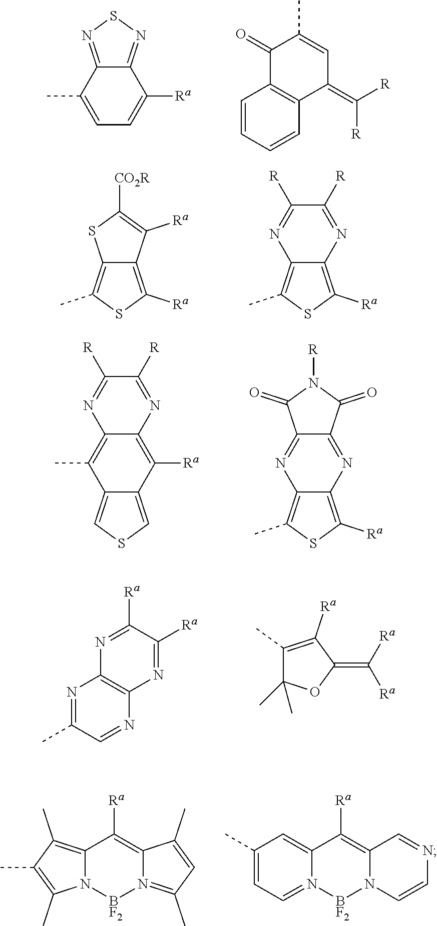

wherein
the dashed line indicates a direct bond to D;
each R is independently selected from the group consisting of hydrogen or a substituent selected from the group consisting of deuterium, C₁-C₂₀ alkyl, C₁-C₂₀ heteroalkyl, C₅-C₁₆ aryl, C₂-C₁₆ heteroaryl, C₅-C₁₆ cycloalkyl;
each R^{a} is independently an electron withdrawing group; and
wherein any two adjacent R or R^{a} may optionally join to form a ring.

In one embodiment, R is C₄-C₂₀ alkyl, C₃-C₂₀ heteroalkyl, C₅-C₁₆ aryl, C₂-C₁₆ heteroaryl, or C₅-C₁₆ cycloalkyl.

In one embodiment, the dihedral angle between best least squares planes of the D group and the least square planes of A¹ or A² is greater than about 30°. In one embodiment, the dihedral angle is 10° to 90°. In one embodiment, the dihedral angle is 10° to 80°. In one embodiment, the dihedral angle is 10° to 70°. In one embodiment, the dihedral angle is 10° to 60°. In one embodiment, the dihedral angle is 10° to 90°. In one embodiment, the dihedral angle is 10° to 50°. In one embodiment, the dihedral angle is 10° to 40°. In one embodiment, the dihedral angle is 20° to 90°. In one embodiment, the dihedral angle is 20° to 80°. In one embodiment, the dihedral angle is 20° to 70°. In one embodiment, the dihedral angle is 20° to 60°. In one embodiment, the dihedral angle is 20° to 90°. In one embodiment, the dihedral angle is 20° to 50°. In one embodiment, the dihedral angle is 20° to 40°.

Also described are compounds having General Formula II:

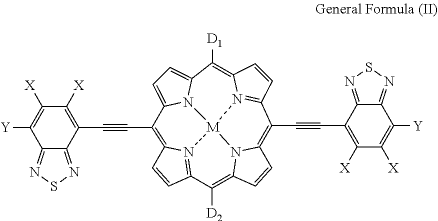

wherein:
M is a metal having a charge of +2;
D1 and D2 are independently hydrogen or a substituent selected from the group consisting of:

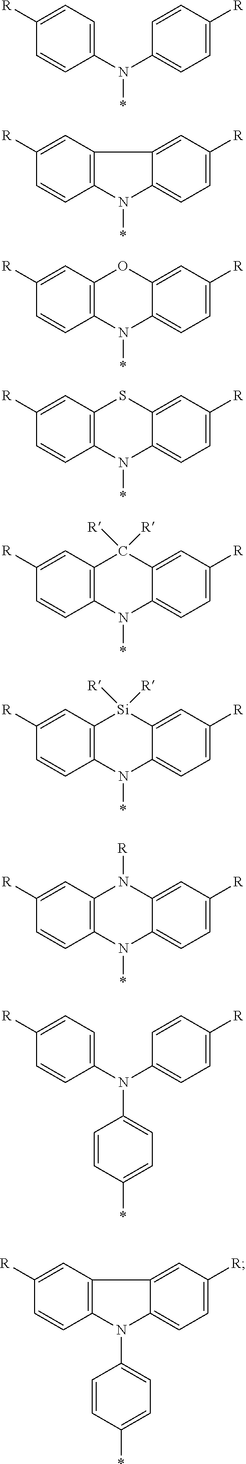

each Y is independently selected from the group consisting of:

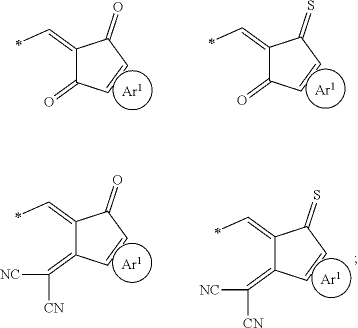

Ar¹ is an aromatic group fused to the adjacent ring and is selected from the group consisting of:

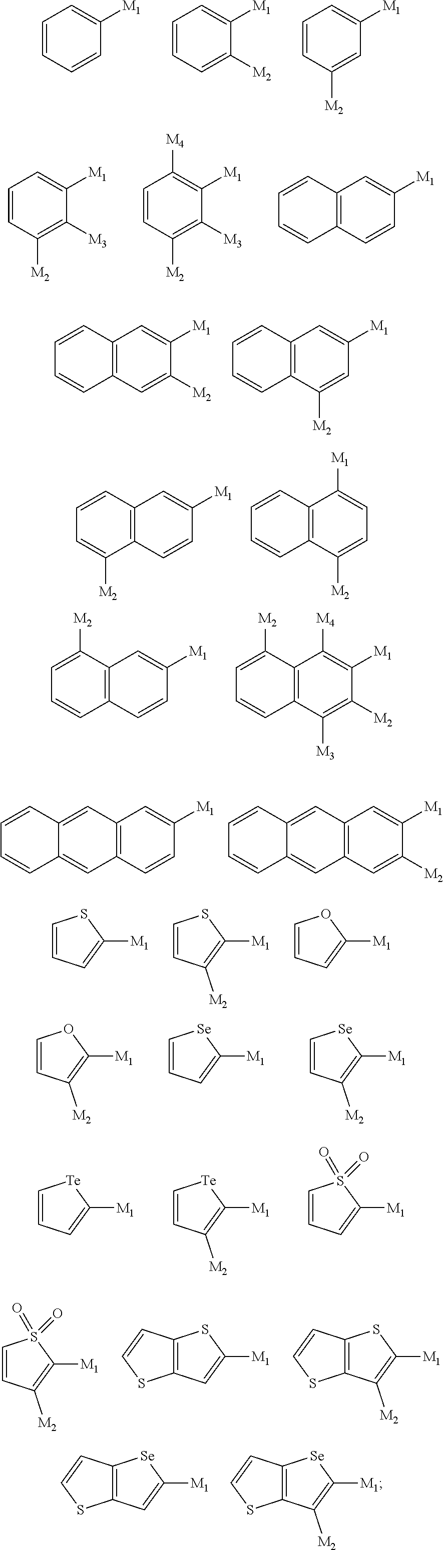

and
each X, M₁, M₂, M₃, M₄, R and R′ is independently hydrogen or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof;
provided that at least one of M₁, M₂, M₃, and M₄ represents a halogen.

In one embodiment, each R independently represents alkyl, alkenyl, or a combination thereof. In one embodiment, each R independently represents C₁-C₂₀ alkyl optionally comprising one or more internal alkenyl groups. In one embodiment, each R independently represents an aryl group further substituted with alkyl, alkenyl, or a combination thereof. In one embodiment, each R independently represents aryl substituted with C₁-C₂₀ alkyl.

In one embodiment, the compound of General Formula II is represented by the following compound:

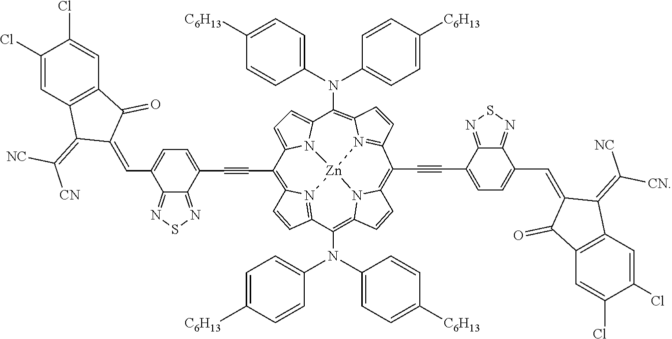

In one embodiment, the compound is represented by General Formula III:

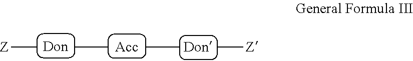

wherein Don and Don′ are each independently represented by Formula A or Formula B:

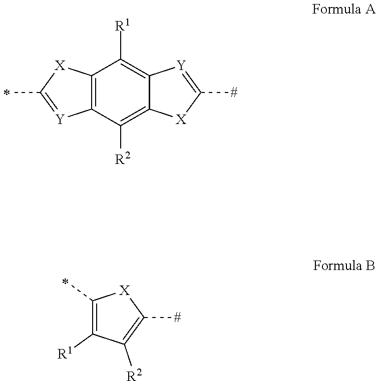

wherein, in Formula A and Formula B:
* represents the bond to Acc;
# represents the bond to Z or Z′;
each X is independently selected from the group consisting of O, S, Se, Te, GeRR′, CRR′, SiRR′, and NR.
each Y is independently selected from the group consisting of N and CR″.
R¹, R², R, R′, and R″ independently represent hydrogen or a substituent selected from the group consisting of deuterium, halogen, alkyl, cycloalkyl, heteroalkyl, heterocycloalkyl, arylalkyl, alkoxy, aryloxy, amino, thioalkyl, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; and any two adjacent substituents optionally join to form a ring;
Acc is a divalent electron accepting group;
Z and Z′ are each together donating groups D and D′ respectively or accepting groups A and A′ respectively;
wherein each of Acc, Z, and Z′ may be further substituted with one or more substituents selected from the group consisting of deuterium, halogen, alkyl, cycloalkyl, heteroalkyl, heterocycloalkyl, arylalkyl, alkoxy, aryloxy, amino, thioalkyl, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
wherein any two adjacent substituents optionally join to form a ring.

In one embodiment, Acc is an electron accepting group selected from the group consisting of SO₂, CF₂, imine, ketone, polycyclic aromatic, polycyclic heteroaromatic, alkyl-borate, aryl-borate, alkoxy-borate, and combinations thereof;

In one embodiment, D and D′ are independently selected from the group consisting of alkoxy, aryloxy, heteroaryloxy, alkenyloxy, alkyloxy, allyloxy, amino, dialkylamino, diarylamino, thioalkyl, thioaryl, thioheteroaryl, and combinations thereof; and

In one embodiment, A and A′ are independently selected from the group consisting of halogen, NO₂, CN, SO₂R, CF₃, imine, ketone, aldehyde, polycyclic aromatic, polycyclic heteroaromatic, alkyl-borate, aryl-borate, alkoxy-borate, and combinations thereof; and

In one embodiment, each of Acc, Z, and Z′ may be further substituted with one or more substituents selected from the group consisting of deuterium, halogen, alkyl, cycloalkyl, heteroalkyl, heterocycloalkyl, arylalkyl, alkoxy, aryloxy, amino, thioalkyl, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; wherein any two adjacent substituents optionally join to form a ring.

In one embodiment, the compound is represented by General Formula IV:

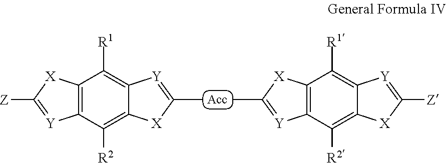

wherein, in General Formula IV,
Acc is a divalent electron accepting group selected from the group consisting of polycyclic aromatic, polycyclic heteroaromatic, aryl-borate, alkoxy-borate, and combinations thereof;
each X is independently selected from the group consisting of O, S, Se, Te, GeRR′, CRR′, SiRR′, and NR;
each Y is independently selected from the group consisting of N and CR″.
Z and Z′ are each together donating groups D and D′ respectively or accepting groups A and A′ respectively;
D and D′ are independently selected from the group consisting of alkoxy, aryloxy, heteroaryloxy, alkenyloxy, alkyloxy, allyloxy, amino, dialkylamino, diarylamino, thioalkyl, thioaryl, thioheteroaryl, and combinations thereof;
A and A′ are independently selected from the group consisting of halogen, NO₂, CN, SO₂R, CF₃, imine, ketone, aldehyde, polycyclic aromatic, polycyclic heteroaromatic, alkyl-borate, aryl-borate, alkoxy-borate, and combinations thereof;
R¹, R^{1′}, R², R^{2′}, R, R′, and R″ independently represent hydrogen or a substituent selected from the group consisting of deuterium, halogen, alkyl, cycloalkyl, heteroalkyl, heterocycloalkyl, arylalkyl, alkoxy, aryloxy, amino, thioalkyl, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; and
any two adjacent substituents optionally join to form a ring.

In one embodiment, at least one of R¹ and R² is represented by one of the following structures:

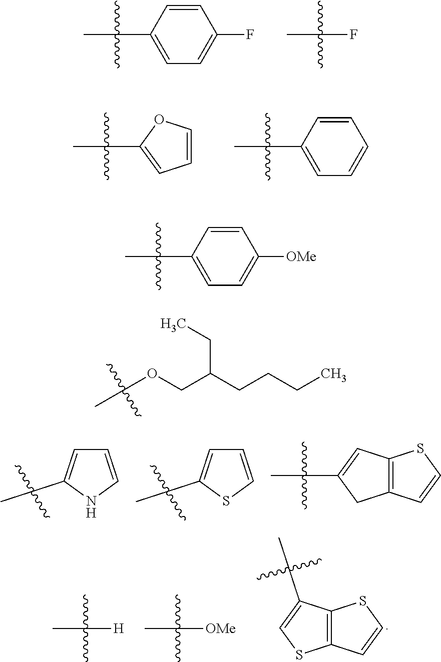

In one embodiment, Acc is represented by one of the following structures:

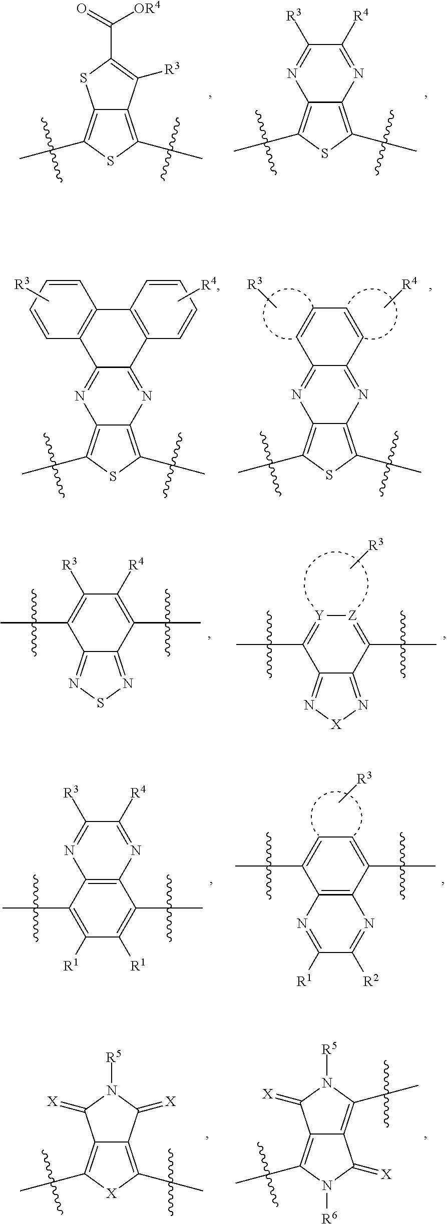

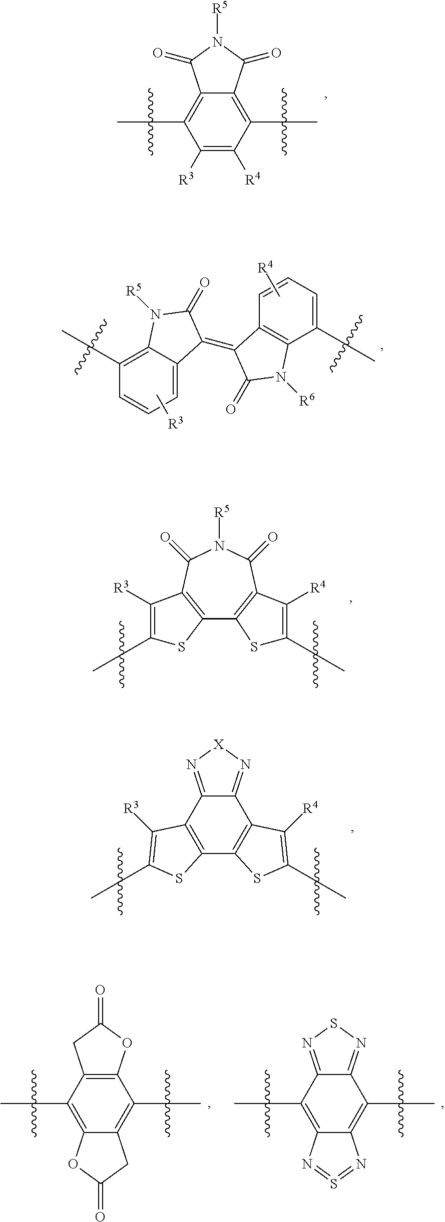

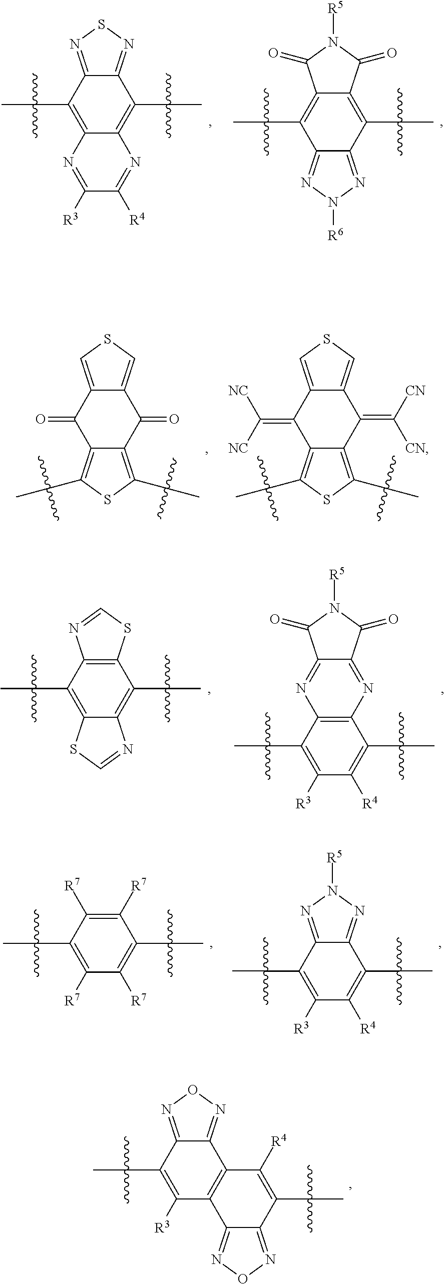

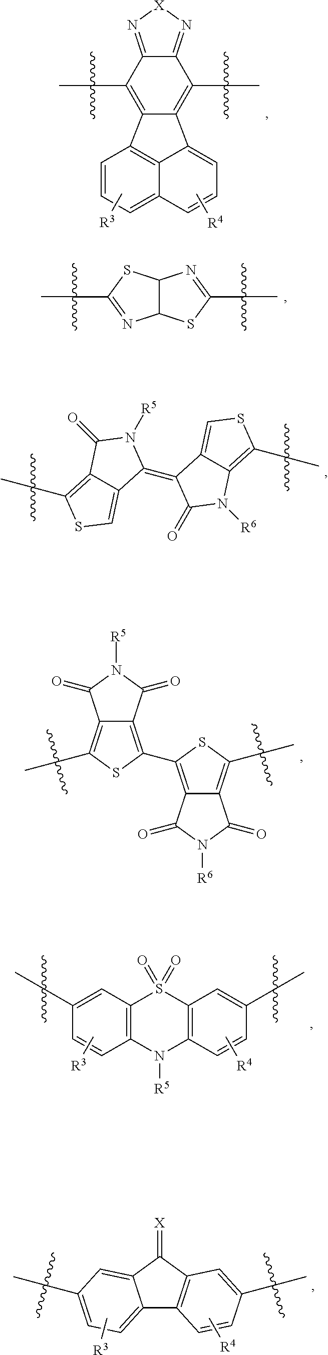

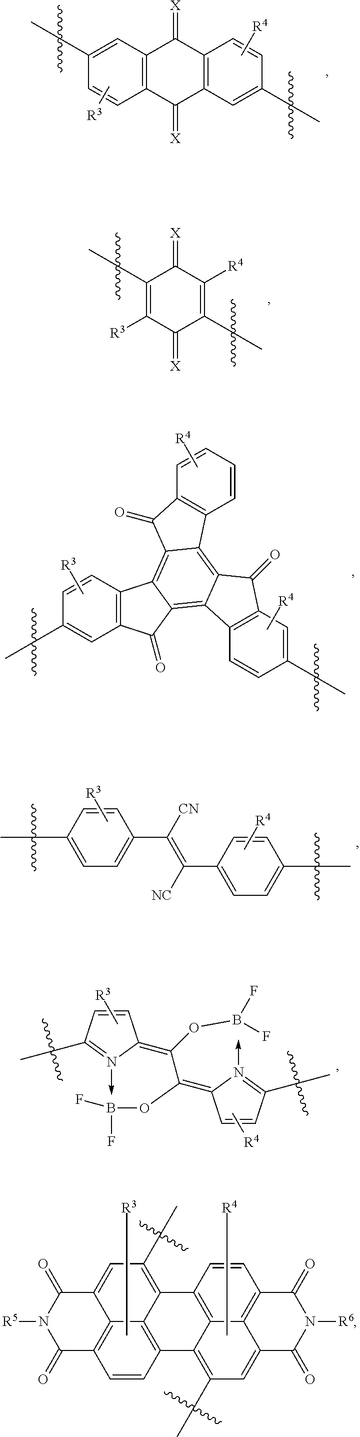

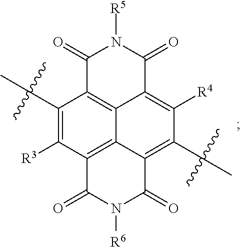

wherein wavy lines indicate bonds to Don and Don′;
wherein each X independently represents O, S, Se, NR⁵, or C(CN)₂;
wherein Y and Z independently represent CR₄ and N;
wherein [symbol] represents optional aryl, heteroaryl, polyaromatic, or polyheteroaryl ring fusions;
wherein R³, R⁴, R⁵, and R⁶ independently represent hydrogen or a substituent selected from the group consisting of deuterium, halogen, alkyl, cycloalkyl, heteroalkyl, heterocycloalkyl, arylalkyl, alkoxy, aryloxy, amino, thioalkyl, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
wherein each R⁷ is independently an electron-withdrawing group selected from the group consisting of halogen, haloalkyl, aryl, heteroaryl, nitrile, and combinations thereof; and
wherein any two adjacent substituents optionally join to form a ring.

In one embodiment, Z and Z′ are independently represented by one of the following structures:

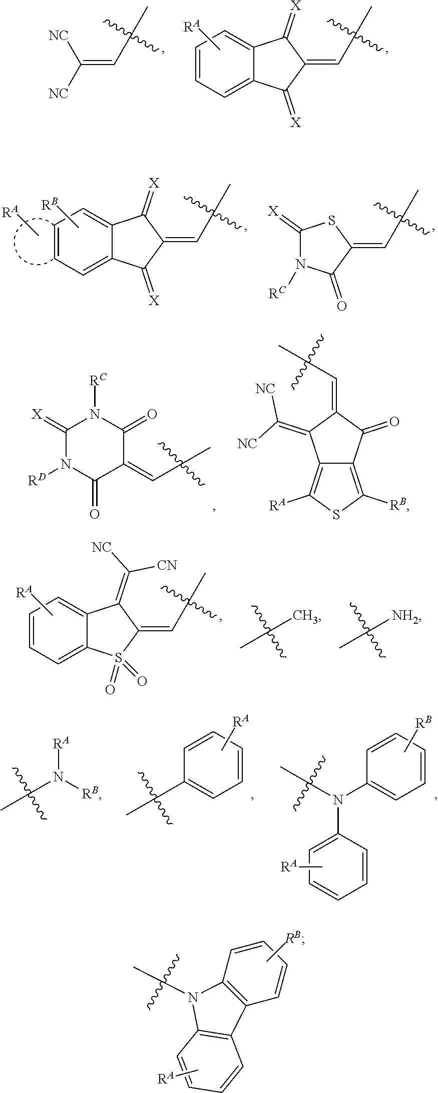

wherein each X independently represents O, S, Se, NRC, or C(CN)₂;
R^{A}, R^{B}, R^{C}, and R^{D} independently represent hydrogen or a substituent selected from the group consisting of deuterium, halogen, alkyl, cycloalkyl, heteroalkyl, heterocycloalkyl, arylalkyl, alkoxy, aryloxy, amino, thioalkyl, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
wherein any two adjacent substituents optionally join to form a ring.

In one embodiment, Z and Z′ are each an acceptor group selected from the group consisting of:

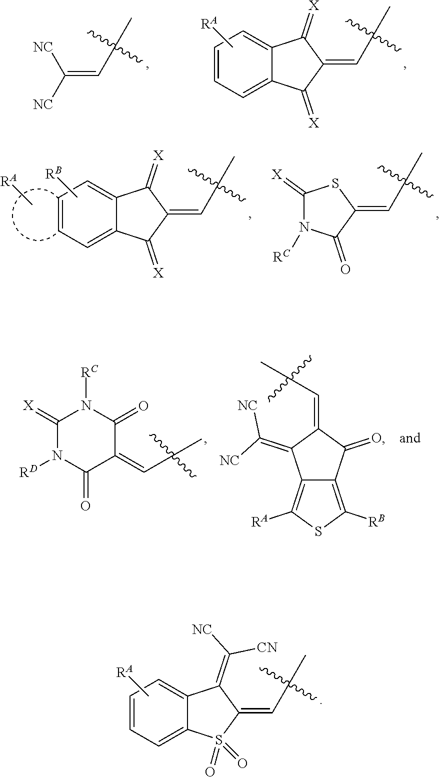

In one embodiment, Z and Z′ are each a donor group selected from the group consisting of:

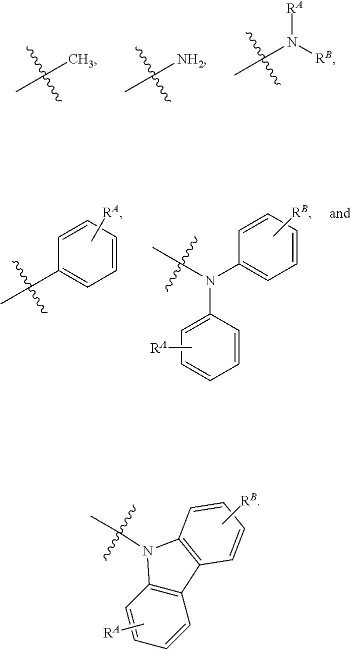

In one embodiment, Acc is selected from the group consisting of:

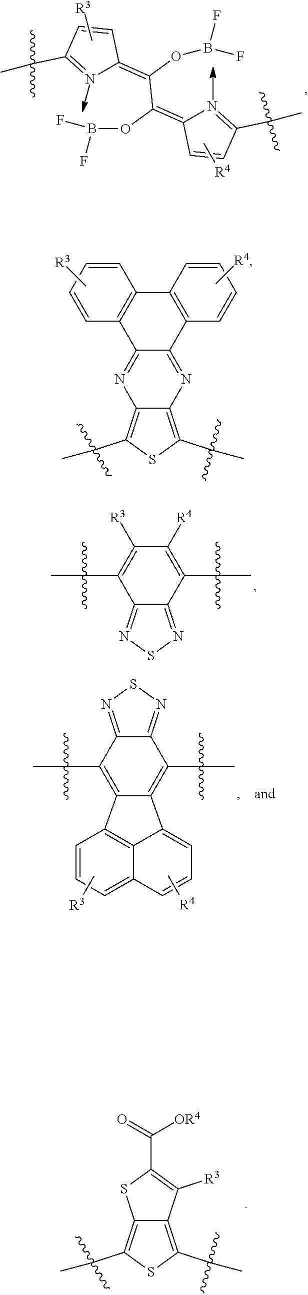

In one embodiment, the compound is represented by one of the following structures:

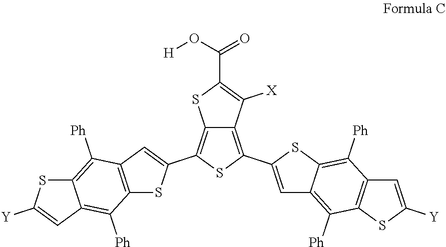

wherein, in Formula C:
X is F, CF₃, CN, SO₃H, or SO₂Me; and
Y is NH₂, NMe₂, NPh₂, N(4-OMePh)₂, N(3,4,5-(OMe)Ph)₂, or N(2,4,6-(OMe)Ph)₂;

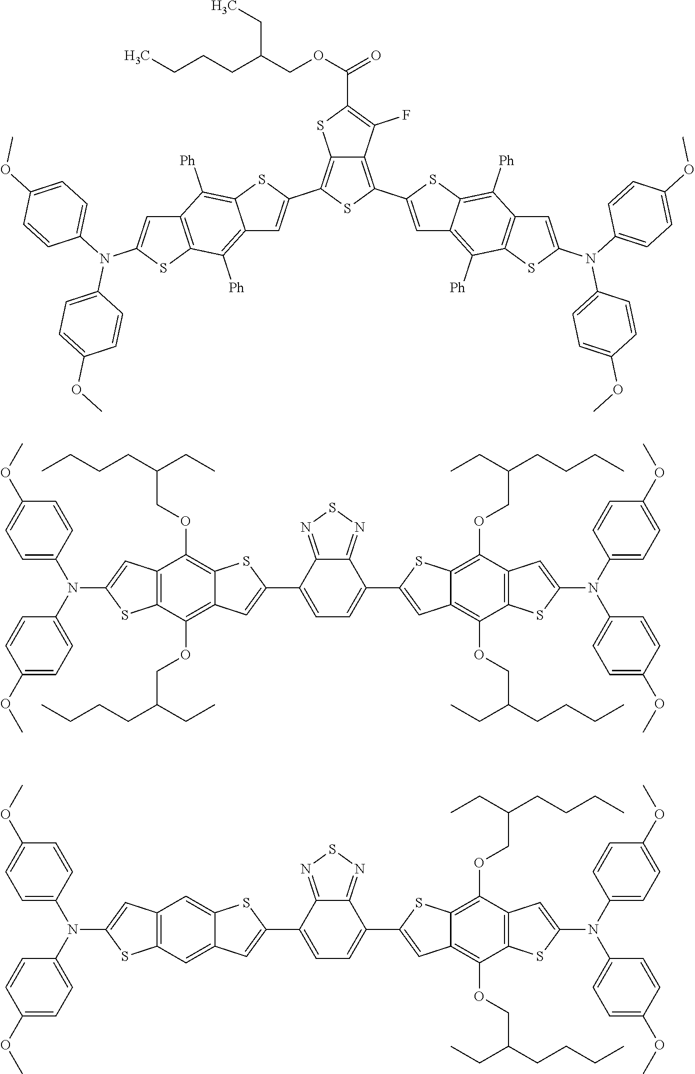

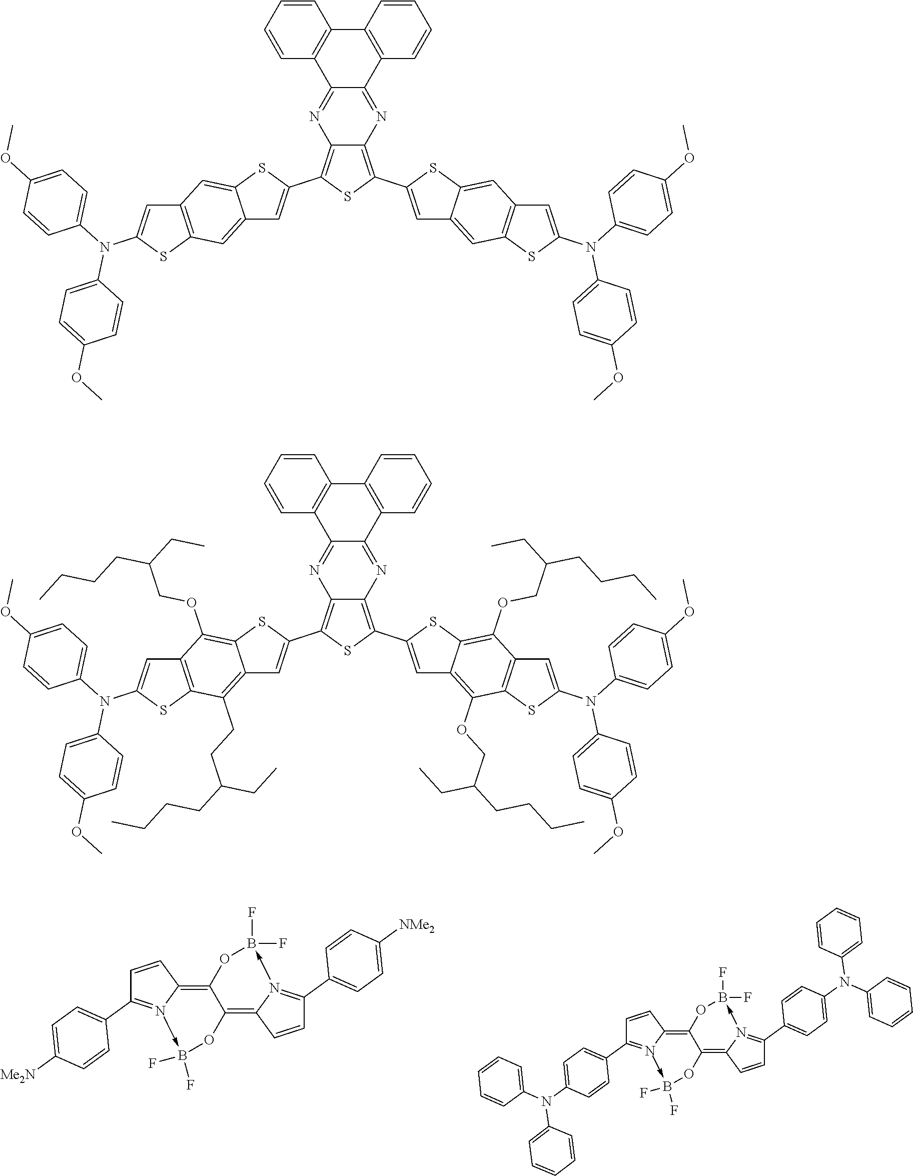

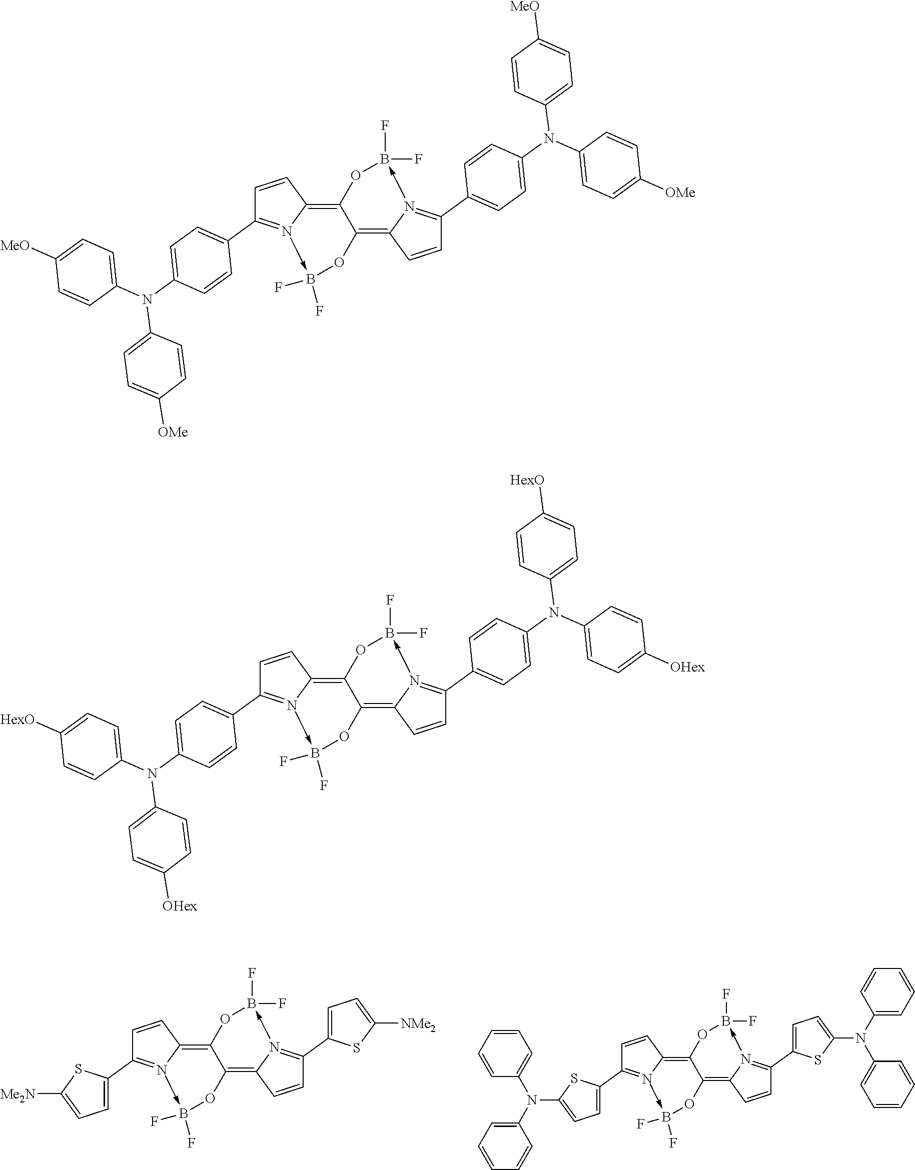

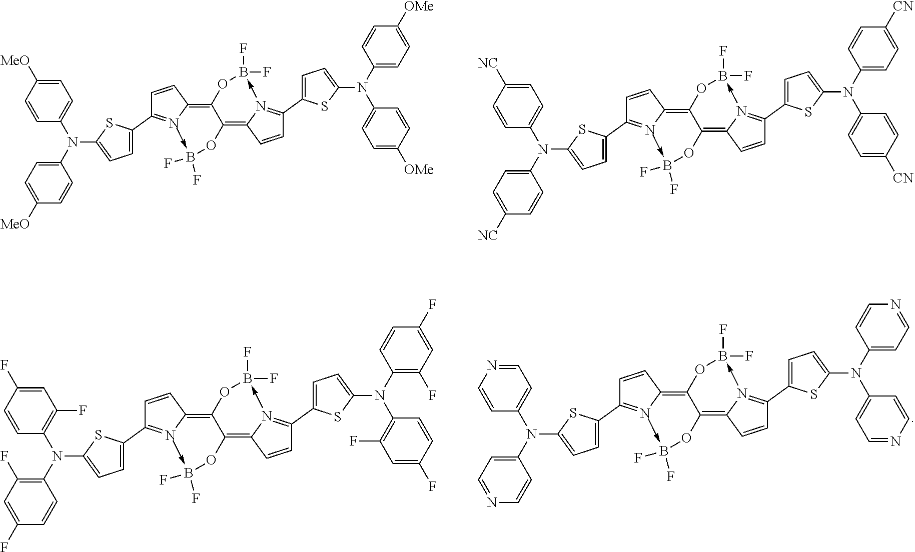

### EXPERIMENTAL EXAMPLES

### Example 1: Factors Controlling Thermally Activated Delayed Fluorescence (TADF) for Organophotovoltaics

One of the most critical challenges currently facing mankind and our planet is how do we slow down or stop the pace at which climate change from carbon dioxide emissions is occurring. The increasing energy demand and its adverse impact on the environment create a pressing need for developing large-scale deployment of renewable energy technologies, in particular solar. Inorganic photovoltaics has been growing rapidly and is currently dominating the solar market. In contrast to the toxic materials and high temperature processing involved in making inorganic semiconductors from materials like silicon and gallium arsenide, Organic materials are inexpensive and use very little energy in their production compared with inorganic electronic materials. They are often environmentally benign and easily disposed of, and they can be deposited onto almost any surface. In particular, the performance of organic photovoltaic (OPV) devices has drastically improved over the last few decades, with power conversion efficiencies (PCE) now approaching 20% (Fu, J. et al. Nat. Commun. 14, 1760 (2023)). This is due to the advent of non-fullerene electron acceptors (NFAs), which have largely replaced the more conventional fullerene acceptors. Non-fullerenes offer multiple benefits over fullerenes, including substantially higher absorptivity and greater synthetic tuning for specific matching to a donor, with their typically planar structures often enabling improved electron mobilities (Li, Y., et al. Nat. Rev. Mater. 8, 186-201 (2023)).

To enable organic photovoltaics to be competitive on the world stage, one of the most critical factors still to be solved is non-radiative decay back to the ground state. Within the context of OPVs, nonradiative decay usually refers to the relaxation of the interfacial donor/acceptor charge transfer state back to the ground state without photon emission, thereby losing the potential energy as heat. Even with the introduction of highly efficient non-fullerene acceptors pushing efficiencies close to 20%, non-radiative decay remains a major loss mechanism.

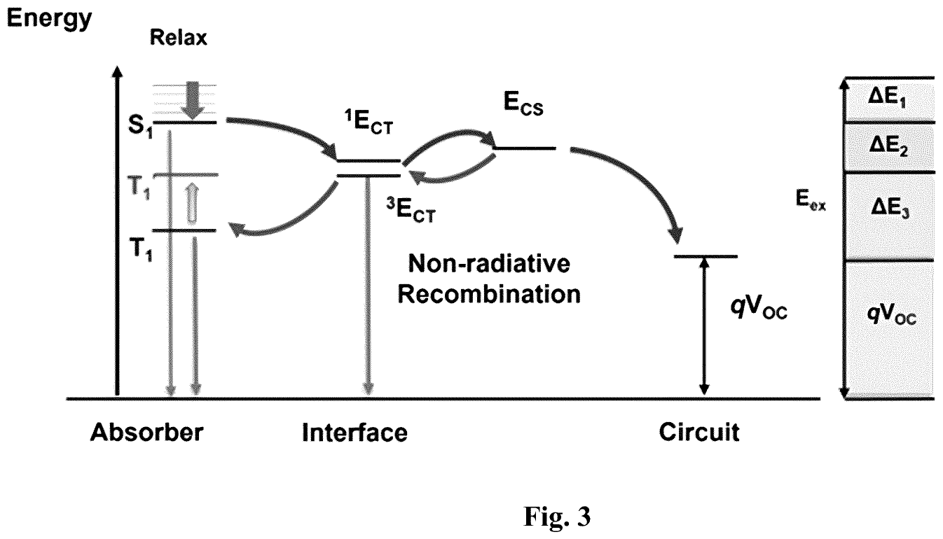

Triplet states commonly form during the operation of OPV cells by bimolecular recombination of free carriers (Gillett, A. J. et al. Nature 597, 666-671 (2021)). Considering that triplet T₁ state is often one of the lowest energy states of the system, for example, its formation and subsequent relaxation back to the ground state entail a non-radiative voltage loss, the reverse transition from the charge transfer ³CT state back to the triplet state becomes more viable, thus providing another avenue for the non-radiative decay loss. As shown in FIG. 3, the Δ E_{S-T} in NFAs is typically large, on the order of 0.4 eV. However, reducing this exchange energy has the potential advantage of allowing triplet recycling via reverse intersystem crossing (RISC). Reducing ΔE_{S-T} is also necessary for thermally activated delayed fluorescence (TADF), a key strategy for enhancing organic light emitting diode (OLED) efficiencies. As such, the same orbital decoupling strategies employed in the TADF-OLED field could also be applicable for OPVs.

Herein is disclosed a series of NFA materials with reducing the ΔE_{S-T}, which is critical to enhancing the reverse intersystem crossing. In certain examples, the non-fullerene acceptor composition is a compound having the following structure:

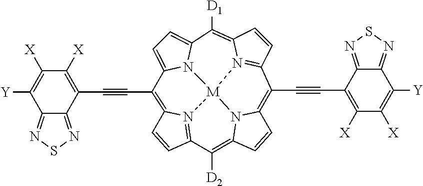

wherein:
D1 and/or D2 is selected from the group consisting of:

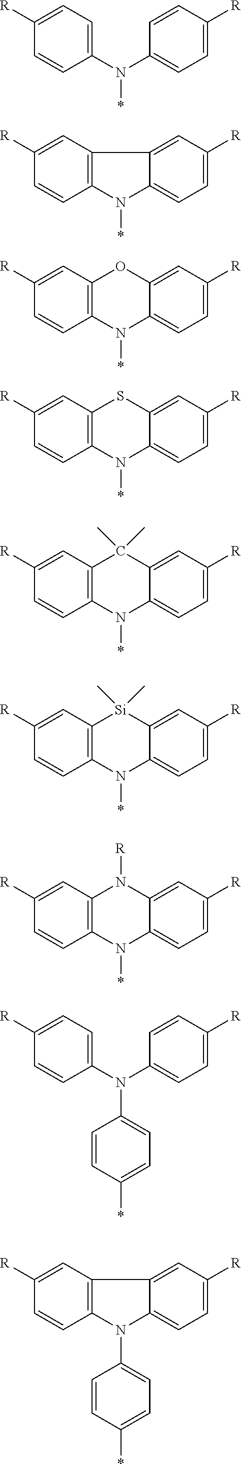

R is a linear or branched saturated or unsaturated non-aromatic hydrocarbon (e.g., within the C₀-C₂₀ range);
Y is selected from the group consisting of:

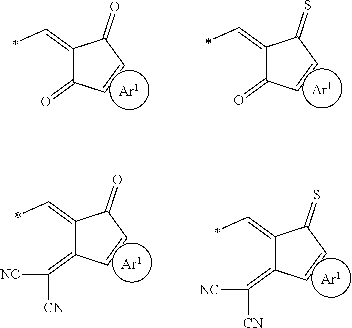

Ar¹ is an aromatic group, which is conjugated fused connected to an adjacent ring, is selected from the group consisting of:

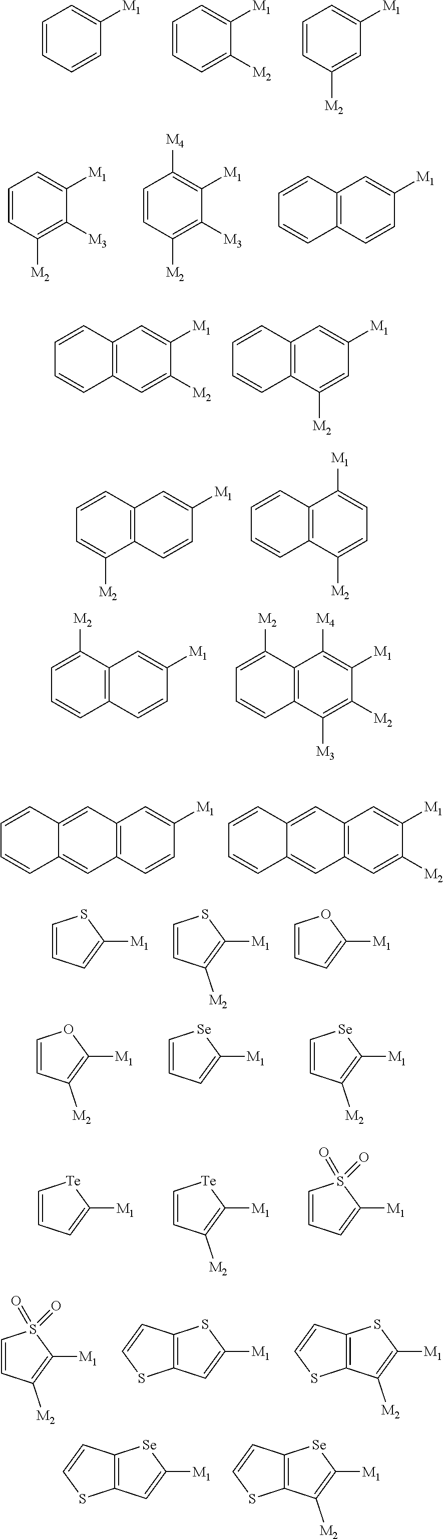

M₁-M₄ is independently selected from the group consisting of hydrogen, fluorine, chlorine, bromine, iodine, and cyano group, wherein at least one of M₁-M₆ is a halogen;
X is selected from the group consisting of chlorine, fluorine, and hydrogen.

One example of a target molecule is depicted below:

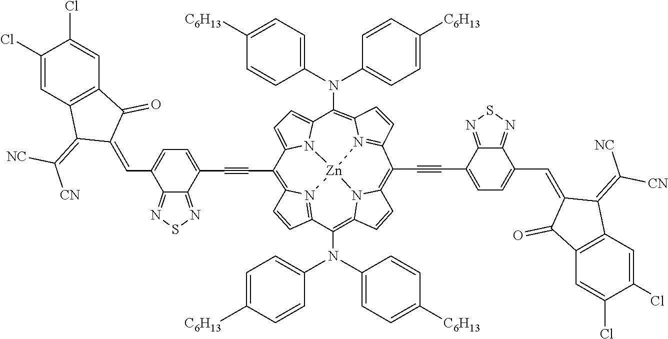

Calculations with this class of compounds reveal a very small ΔE_{ST}. Calculations were done with B3LYP/LACVP; the results were the same with LANL2DZ

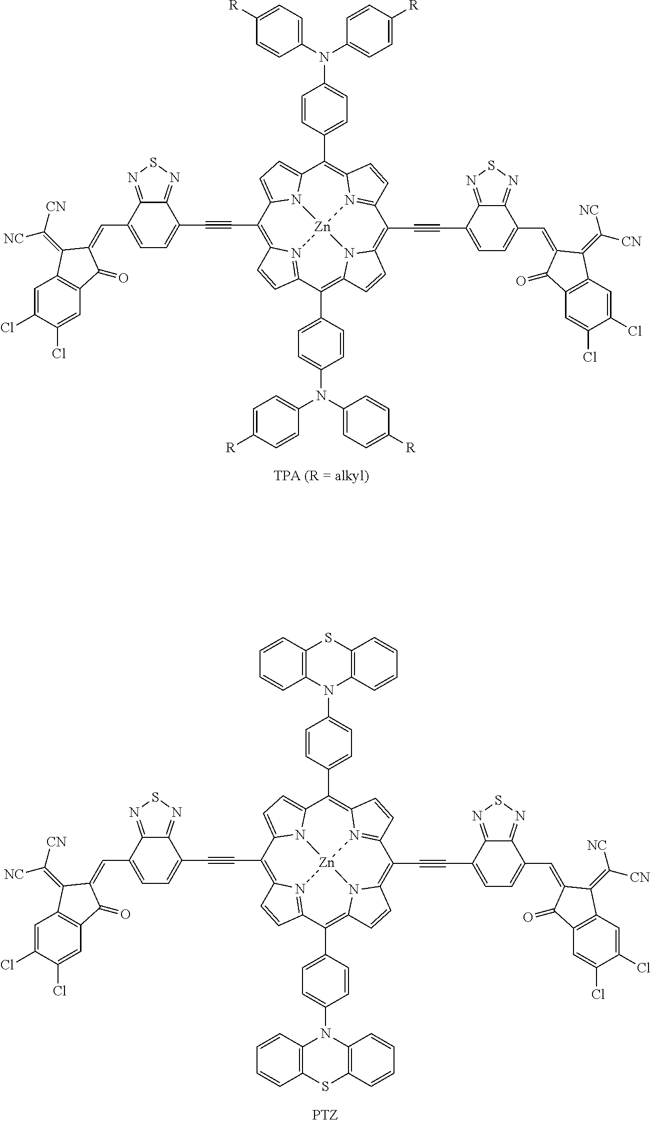

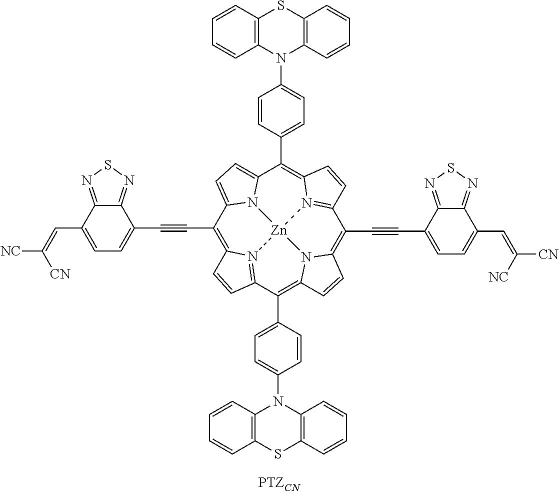

| Donor | HOMO (eV) | LUMO (eV) | S₁ (eV) \| f | T₁ (eV) | ΔE_{ST} (eV) | Sₙ (eV) \| f |
|---|---|---|---|---|---|---|
| TPA | −5.11 | −4.03 | 0.88 \| 0.19 | 0.70 | 0.18 | 1.37 \| 2.36 |
| PTZ | −5.24 | −4.13 | 0.88 \| 0 | 0.86 | 0.02 | 1.39 \| 2.38 |
| PTZ_{CN} | −5.24 | −4.09 | 0.92 \| 0 | 0.86 | 0.06 | 1.48 \| 1.61 |

### Example 2: TADF Materials for High Performance Organic Photovoltaics

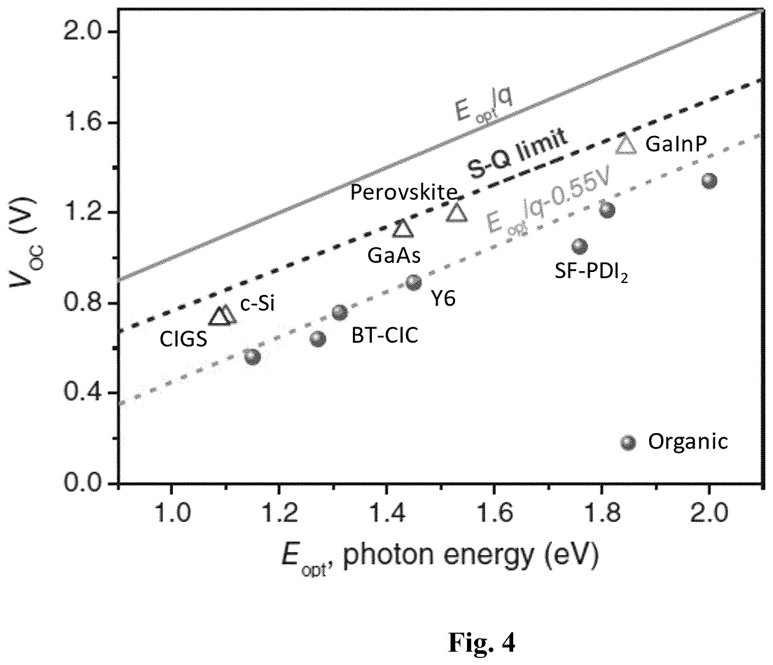

OPVs have become a subject of intense interest due to their steadily increasing efficiencies and potentially lower costs than conventional binary cells. Single junction cells have achieved a power conversion efficiency of PCE=19.4%, which is exceeded only by tandem cells comprising two binary subcells. Despite their relatively high efficiency, OPVs have two significant deficiencies. The first is that the efficiency still falls well below those of inorganic solar cells fabricated from crystalline silicon (c-Si), CIGS, GaAs and perovskites. This is primarily a result of a ˜20% higher energy loss Eₗₒₛₛ=Eₒₚₜ−V_{OC} of OPVs vs. those competing technologies, as shown in FIG. 4. Here, the open circuit voltage is V_{OC}, and the photon energy is Eₒₚₜ. The solid line represents the radiative V_{OC} limit, defining the Shockley-Queisser (SQ) limit of PCE=31%. Interestingly, while Y6 has achieved the record high single junction cell efficiencies, its Eₗₒₛₛ is comparable to all high performance NFAs. The source of the loss from the various technologies are apparent from the data in Table 1. There is a much larger non-radiative component to the V_{OC} loss (DV_{OC,nr}) for OPVs compared with competing technologies. This is reflected in the very low OPV electroluminescent external quantum efficiency of EQE_{EL}=0.01% obtained via forward biasing the PV, compared to 35.7% for the highest performing GaAs system. (Note that Kirchoff's law requires that a perfect absorber is also a perfect emitter.)

### Table 1: Comparison of Losses of Several PV Technologies

| Material | PCE (%) | E_{g}-qV_{OC} (V) | ΔV_{OC, nr} | EQE_{EL} (%) |
|---|---|---|---|---|
| c-Si | 26.7 | 0.36 | 0.107 | 1.6 |
| GaAs | 29.1 | 0.31 | 0.027 | 35.7 |
| Perovskite | 25.6 | 0.34 | 0.059 | 10.1 |
| Organic | 19.2 | 0.56 | 0.240 | 0.01 |

A principal source of inefficiency in OPVs is the excess energy loss in the photogeneration process, illustrated in FIG. 3 (Li, et al. Nature Reviews Materials, 8, 186-201 (2023)) The formation of the charge-transfer (CT) state at the D-A interface incurs nonradiative energy loss (ΔE₂) during Frenkel exciton dissociation. A ‘hot’ CT state can endothermically transfer to the charge-separated (CS) state, ultimately resulting in a free charge pair. However, in such a scheme there is also a significant chance that CS states may non-geminately recombine back into a CT state. Spin statistics dictate that the probability for singlet (i.e. radiative) ¹CT formation upon electron-hole encounter is ¼, while the chance for forming a triplet ³CT state is ¾. Triplet CT states are in principle not coupled to the ground state, but can convert to local triplet states, T₁, which then non-radiatively decay leading to a further significant energy loss, ΔE₃, with a concomitant decrease in V_{OC}.

Closing the singlet-triplet exchange energy gap, ΔE_{ST}, is critical to eliminating nonradiative losses. Described herein are materials that have T₁ energies close to the related S₁ states and also are higher in energy than the CT state. Hence, back transfer to the T₁ state rapidly repopulates the radiative S₁ state, resulting in ΔE₃→0. Such a strategy closes the efficiency gap between OPVs and other thin film solar cell technologies. Thus, this disclosure describes the design of a new generation of OPV materials with exceptionally low exchange energies, using molecules that have comparatively low cost, while satisfying the other constraints needed for an active OPV material.

The Donor, D, and Acceptor, A, materials developed here are designed to have their lowest energy excited state be an intramolecular charge transfer state, ICT. In order to not confuse the intramolecular charge transfer (ICT) excited state from the CT that ultimately leads to free charges, the notation a and d is used to designate the intramolecular acceptor and donor groups and A and D are used to represent the acceptor and donor materials that comprise the heterojunction in the OPV. Thus, a nonfullerene acceptor, NFA, would be represented as ada, and the excited ICT state of the NFA as a^{1/2-}d⁺a^{1/2-} (Luo, et al., J. Mater. Chem. A, 2022, 10, 3255-3295; Yan, et al., Nat Rev Mater 3, 18003 (2018); Zhou, et al. Nano Energy, 103A, 107802 (2022)) Excited A or D give rise to charge transfer state, CT, forming as an exciplex at the interface between the two materials, i.e. [A⁻D⁺]. This exciplex CT has singlet and triplet spin configurations, but they are nearly degenerate due to the hole and electron being on separate molecules.

There are a number of parameters that need to be considered in designing active materials for OPVs: (1) the combination of the A and D materials need to efficiently absorb solar radiation from violet to the NIR (out to 1.2 eV in the program), (2) D/A need to give a heterojunction that efficiently forms the CT state (D*A→[A⁻D⁺] or DA*→[A⁻D⁺]), (3) the materials must form a nanophase separated film that efficiently transports carriers to the collecting electrodes (Schlenker and Thompson; Chem. Commun., 2011, 47, 3702-3716; Hedley, et al., Chem. Rev. 2017, 117, 2, 796-837; Solak and Irmak, RSC Adv., 2023, 13, 12244-12269). In some cases, an added requirement is that the NIR absorber must have a small ΔE_{ST} (<0.10 eV)

Achieving very small ΔE_{ST} values has been demonstrated in both organic and organometallic compounds, with their principal application being organic LEDs (Muthiah Ravinson and Thompson, Mater. Horiz., 2020, 7, 1210-1217; Shi, et al. Chem. Sci., 2022, 13, 3625-3651; Im, et al., Chem. Mater. 2017, 29, 5, 1946-1963; Xiao, et al., Chem. Sci., 2022, 13, 8906-8923). In an OLED carrier recombination leads to both singlet and triplet excited states. A small ΔE_{ST} allows the triplet to thermally populate the singlet and emit via thermally assisted delayed fluorescence, TADF. These TADF-based OLEDs have high EL efficiency, which is our goal here for OPVs as well. ΔE_{ST} values for TADF based emitters have been reported in the 10-30 meV range, well below the target here. While TADF emitters seem to fit the bill for our OPV materials, they have two critical flaws: in some cases, reported TADF emitters do not absorb substantially in the visible to NIR region and more importantly they have absorptivity, typically <10³ cm⁻¹. The small ΔE_{ST} is achieved by limiting the overlap of the hole and electron wavefunctions in the ICT state, minimizing the exchange energy and thus decreasing ΔE_{ST}. Structures are used that lead to twisting of the a and d groups of the compound, to a nearly orthogonal configuration. This limits the exchange energy, but also limits the oscillator strength and it has been found that the two parameters are interrelated (Li, et al, J. Mater. Chem. C, 2022, 10, 4674-4683; Muniz, et al., J. Am. Chem. Soc. 2022, 144, 39, 17916-17928). The ada NFA compounds that have become common in OPVs today use separate a and d groups to form an ICT excited state, a^{1/2-}d⁺a^{1/2-}, minimizing the exciton binding energy, but the a and d groups are effectively conjugated leading to high ΔE_{ST} and high molar absorptivity. The molecules described herein give low ΔE_{ST} without unduly sacrificing in absorptivity and meet all of the other requirements of active OPV materials described above; the compounds achieve ΔE_{ST}<100 meV while maintaining α≥10⁴ cm⁻¹.

These materials discovery efforts begin with theoretical modeling of a wide range of materials. DFT and TDDFT modeling are used to accurately predict S₁ and T₁ energies as well as frontier orbital energies for TADF materials previously; the same methods are applied here to identify the best candidates to move into the laboratory for synthesis and study. Initial materials discovery efforts are directed to finding new acceptor (A) compounds with small ΔE_{ST}. These acceptors are coupled with well-established polymer donors in RAMP and OPV studies. The compounds studied have structures with the following design criteria:

Simple structures for a and d and modular design are used to keep fabrication costs down. Examples of the a and d groups that we will explore in this program are shown below. These compounds have a range of LUMO (for a) and HOMO (for d) energies and are readily available. Pairing different a and d groups will permit tuning of the ICT absorption energies across the visible and into the NIR region of the spectrum. Explored are conventional NFA cores as well as simplified donor cores. The simplified cores illustrated are predicted to have similar donor properties to the “common” cores but can be prepared in only a few synthetic steps, from low cost starting materials, making NFAs with these cores markedly less costly than the previously reported NFAs. These materials are incorporated into full sized panels, and a high cost for previously reported NFAs makes these panels impractical for real world application.

LUMO and HOMO energies of a and d are adjusted to give visible-to-NIR absorption. A range of materials are prepared with different a and d groups. The modeling work provides good estimates of the absorption energy and oscillator strength (f) of each ada or dad structure. The modeling studies also provide a good estimate of the ΔE_{ST} value for each candidate material. Study begins with the optimized structure, but also explored are structures with the a and d groups largely in plane (conjugated) as well as those with the groups twisted out of plane. The in-plane versions may be expected to give the highest ΔE_{ST} and f, while the twisted ones may be lower values of ΔE_{ST} and f, with minimum values when a and d are at 90° to each other.

Coupling chemistries to control/minimize d-a overlap. It is critical to control the degree of overlap between the a and d groups. Too much overlap and the ΔE_{ST} is too high, too little overlap and the f is too low. The preliminary approach is to find a/d pairs that give the right absorption energy and investigate ΔE_{ST} and f as a function of the twist angle between a and d. Computational constraints can be used to control the angle between the a and d groups, but in the prepared complexes steric interactions of peripheral alkyl groups are used to enforce a given twist angle. These steric interactions can be well modeled computationally as well.

A second approach to controlling the a/d overlap is to couple them though poorly conjugating linkages. These include acetylenic (—C≡C—) groups and meta-substituted arene rings. These linkages lead to inefficient conjugation between groups coupled with them (Korovina, et al., J. Am. Chem. Soc. 2018, 140, 32, 10179-10190; Korovina, et al., Am. Chem. Soc. 2016, 138, 2, 617-627). The steric approach can be used in concert with meta-substituted arene rings, but the acetylenic linkers will limit the steric interactions between a and d.

These studies result in 10-15 candidate materials with low ΔE_{ST} and high f that are prepared so that their physical properties are measured. The materials are tested via RAMP studies and in OPV structures.

d and/or a groups with strong visible light absorption. To achieve the highest efficiency all of the photons in the spectrum into the NIR must be utilized. In order to absorb though the spectrum, OPVs often have three or more active materials. An alternative to this is to build a and d units with multiple chromophores that energy transfer to the final excited state. A similar approach is used in Nature, where antenna chromophores channel energy into the special pair for charge separation. In the materials being studied here we will investigate the use of a and d groups that are good chromophores themselves and couple them into a/d systems. Several examples of chromogenic a and d groups are shown below. All of these have high molar absorptivity, ε=10⁴-10⁵ M⁻¹ cm⁻¹, in the blue to green part of the spectrum. If they are part of an ada system that is tuned to have ICT absorption in the NIR, any light absorbed by the chromophore unit will rapidly and efficiently decay to the ICT state. Explored are a number of candidate structures for this internal energy transfer function in ada and dad structures.

### Donors

Simplified donor cores for ada NFAs: 3-4 steps from inexpensive starting materials:

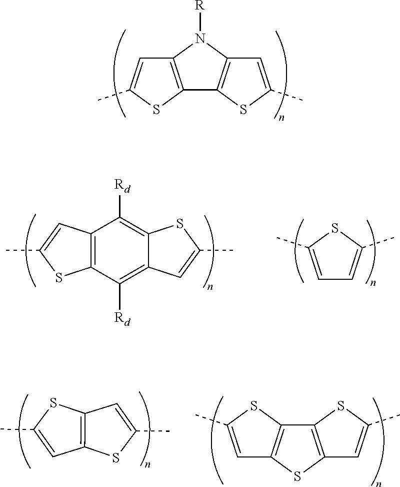

(R=alkyl, aryl, thiophene; R_{d}=thiophene, Ph, OR, NR₂):

Donor cores used in common NFAs: 10-12 steps from costly starting materials.

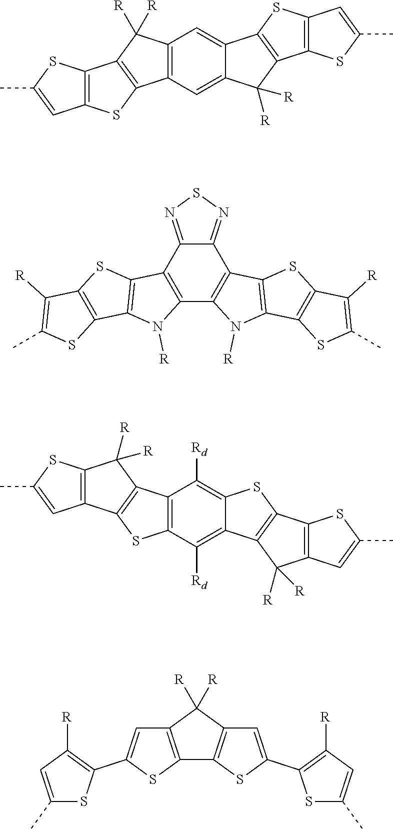

Chromophore donor cores for ada NFAs to be used to sensitize to higher energy:

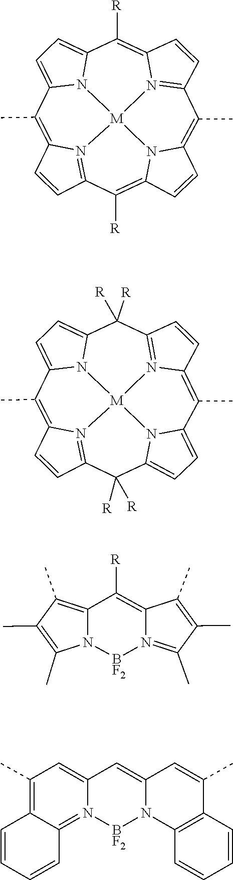

### Acceptors

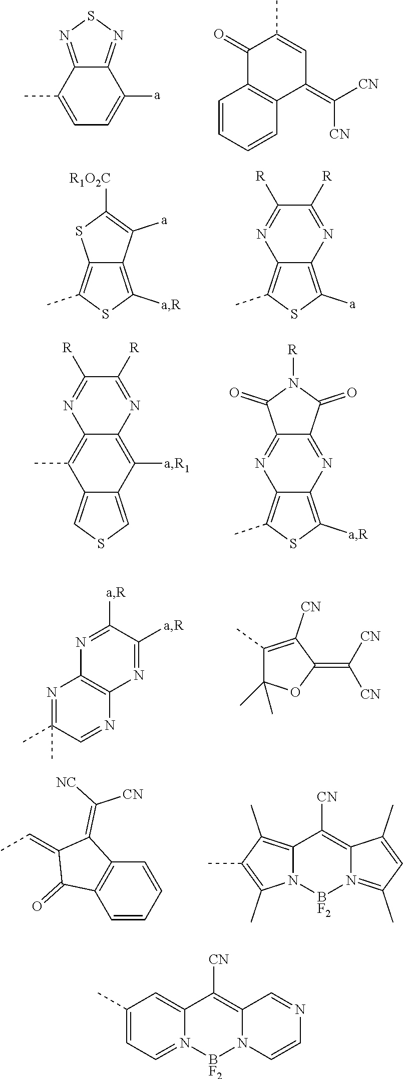

(a=CN, NO2, CH═C(CN)2, SO3R; R=alkyl, aryl, thiophene); note that the IC group

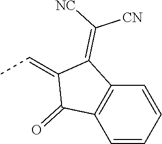

has minimal solubility in solution-processed devices.

High PCE Material Development: Low V_{OC} is a key limiter on the PCE values reported for OPVs. The low triplet energy of the active materials severely limits their radiative efficiency and thus the V_{oc} by recapturing charge separated excitons into the nonradiative triplet (see introductory section). The solution to this problem is to develop materials with small energy gaps between the S₁ and T₁ to allow for thermal population of S₁ from T₁, while simultaneously raising the energy of T₁ to above the charge transfer (CT) state at the donor (D)-acceptor (A) junction to prohibit back transfer into the triplet (FIG. 3). Density functional theory (DFT) is used to accurately predict S₁, T₁ and frontier orbital energies for OLED materials; these same methods are applied to identify the best candidates for synthesis of high efficiency OPV D and A molecules that minimize the S-T exchange energy, ΔE_{ST}, to reduce nonradiative triplet losses (see FIG. 3).

Simple structures for electron withdrawing (a) and donating (d) subunits with modular designs to reduce costs. Pairing different a and d groups such as in the claimed compounds can tune the absorption energies across the visible and into the NIR spectral regions. Conventional NFA molecular cores as well as simplified donor cores are utilized. The simplified cores shown have similar donor properties to the “common” NFA cores and could reduce costs by 5× or more based on reagents and reduced synthetic complexity.

Frontier orbital energies of a and d molecular subgroups are tuned for visible-to-NIR absorption. Modeling work provides estimates of the absorption energy, i.e. oscillator strength (f) and ΔE_{ST} of each a-d-a (A) or d-a-d (D) structure. Both planar and twisted molecular motifs will be explored. Fully planar molecules give the highest ΔE_{ST} and f (hence significant nonradiative losses, but high absorptivity), while the twisted structures give smaller values of ΔE_{ST} and f, with minimums when a and d are orthogonal.

Coupling chemistries will control d-a overlap. It is critical to control the degree of overlap between the a and d groups since too much overlap causes an increase in ΔE_{ST}, whereas a small overlap reduces f. Specific a/d pairs are identified that give ΔE_{ST} and f as functions of the twist angle between a and d, which affords candidate structures that give ΔE_{ST}<0.1 eV while maintaining a high f, leading to an absorption coefficient >10⁴ cm⁻¹. Steric interactions of peripheral alkyl groups are exploited to enforce a given twist angle using modeling to identify the best substitution pattern prior to synthesis.

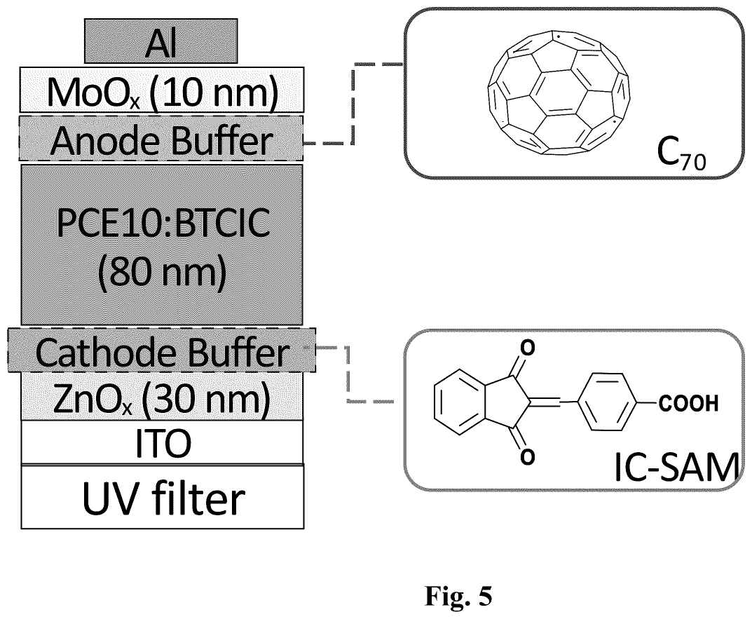

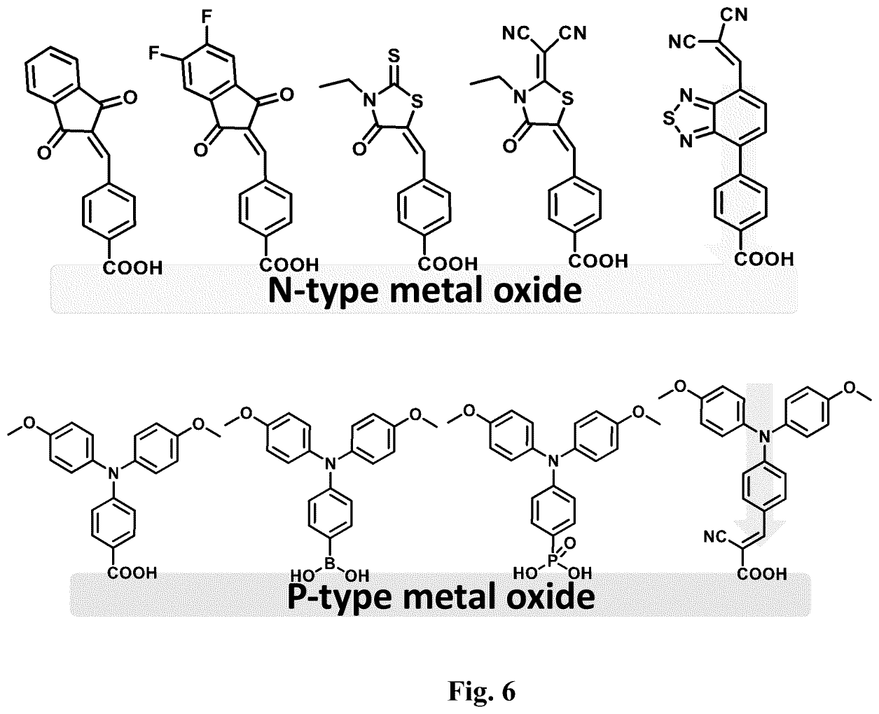

Ultrathin and self-assembled structures (IC-SAM and C₇₀) inserted between the active layer and the transporting layers of OPVs (FIG. 5) eliminate chemically destructive reactions with thiophene-containing NFAs when positioned at the BHJ/ZnO and MoO₃/ZnO interfaces, respectively, leading to laboratory cell extrapolated lifetimes of 30 yr or more. Similar modeling and buffering approaches are carried out to determine whether these long-term reliability results apply to the high efficiency small ΔE_{ST} molecules. Hence, a new family of interface buffering layers are prepared, shown in FIG. 6 by example. For n-type metal oxide buffers, self-assembled monolayers functionalized using electron-withdrawing groups are used, whereas triarylamine groups are tied to hydroxyl anchors to protect the active region at the p-oxide interface. These simple molecules are synthesized or purchased from commercial vendors if available.

It is important to coat the sun-facing surface of substrates with 600 nm ZnO to protect against high energy photo-chemical damage of the active layer. The coating serves as a UV filter with a cutoff just below 400 nm, and exhibits almost 100% transparency at wavelengths into the near infrared.

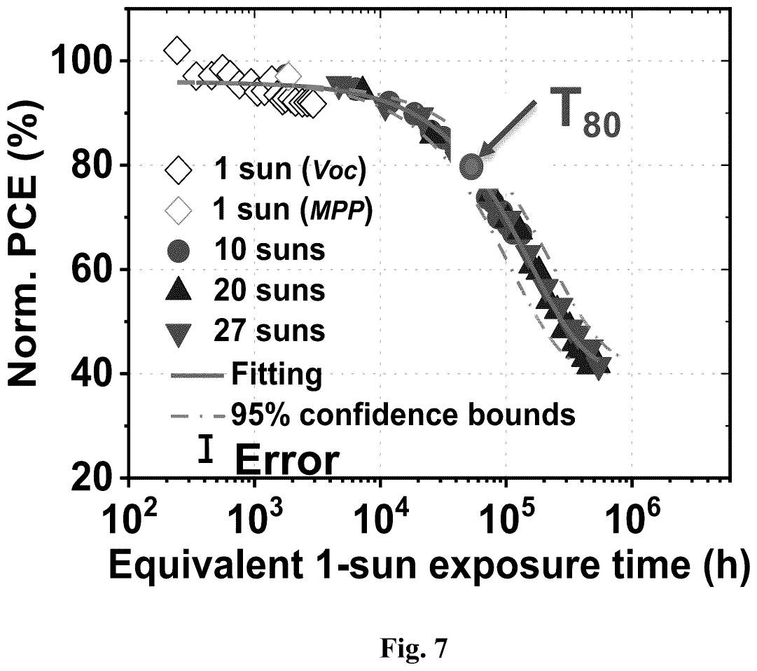

Cells and modules are subjected to accelerated lifetime tests (ALTs). An example plot of a population of NFA-based OPVs tested at U-M under several different visible light intensities is shown in FIG. 7, giving an extrapolated lifetime at 1 sun intensity of 30 yr. ALT can simultaneously test a population of up to 40 actively cooled devices using ultrahigh intensity LED stadium lights. UV exposure is applied separately using high intensity UV LEDs, although as noted above, a solution-deposited ZnO UV filtering layer is highly effective at preventing short wavelength damage to the cell materials. A critical research gap exists between ALT and predicting field-deployed lifetimes.

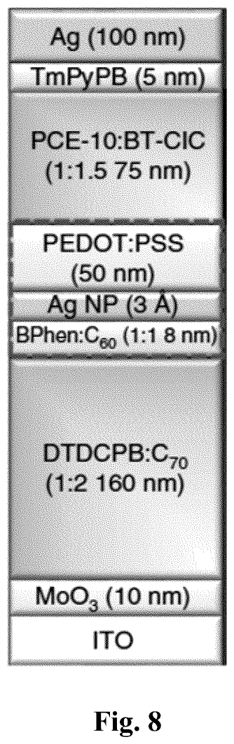

Low-Cost and Efficient Semitransparent (st)-OPV and Multijunction Cell Development: Fabricating tandem OPV cells is remarkably simple. In most respects, combining cells in a vertical stack as shown in FIG. 8 is as simple and straightforward as making a single junction cell—a property that is unique to organic thin film devices. Furthermore, it is equally simple to integrate an OPV with other material base sub-cells since the layering scheme is at very low temperatures and there are no lattice compatibility (e.g. lattice matching, material interdiffusion) issues with other layers in the multijunction. And while semitransparency is the key to unlocking billions of m² of impactful multi-use solar potential, many of the tools used in designing optical coatings for st-OPVs are equally suited for tandem designs. Organic multijunction cells using very high efficiency subcells is an additional route and mitigation strategy to achieve PCE=25%. Furthermore, long wavelength absorbing OPV subcells can be combined with perovskite or CdTe base cells to further enhance their efficiencies.

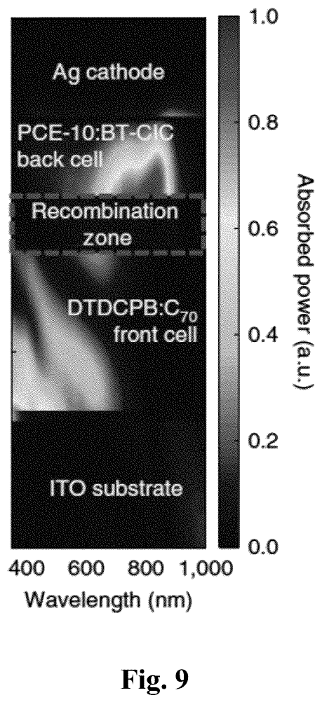

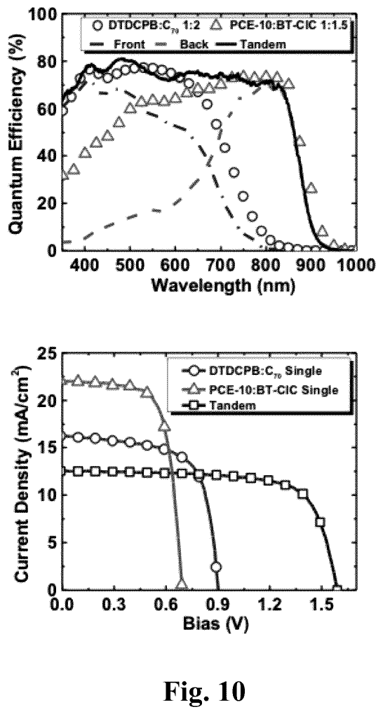

The tandem cell employs a highly transparent and efficient Ag nanoparticle or ZnO charge recombination zone buffered by hole and electron conducting and organic buffers that make connection to the upper and lower elements of the tandem. An example 15% efficient OPV/OPV tandem cell comprising a top, NFA-based cell connected to a bottom vapor-deposited short wavelength cell interconnected with a buffered Ag nanoparticle layer is shown in FIG. 8. FIG. 9 shows the results of an optical model used to design the cell structure. Note the total transparency of the interconnection layer. Also shown are performance results of the tandem cell (FIG. 10) built to this design. Similar processes and modelling such as used in FIGS. 8-10 are applied to the even higher efficiency cells developed in our the workplan disclosed herein.

Three mechanisms that determine the magnitude of V_{oc} are: (i) radiative recombination of optically generated excited states, or excitons, within the donor or acceptor regions; (ii) radiative recombination due to CT state relaxation; and (iii) non-radiative recombination due to defect states or other diode non-idealities. This latter process may result in a voltage loss over time. To quantify these effects, the non-radiative voltage loss, ΔVₙᵣ, is defined as the difference between the open-circuit voltage in the presence of only radiative processes (the radiative limit), V_{oc}^{rad}, and the actual V_{oc} of the cell, viz.:

$$Δ {V}_{nr} = {V}_{oc}^{rad} - {V}_{oc} = \frac{k T}{q} ln ( \frac{{J}_{sc}}{{J}_{0}^{rad}} ) - {V}_{oc} . \qquad ( 1 )$$

Here, J_{sc} is the short circuit current density, J₀^{rad} is the dark saturation current density in the radiative limit (i.e. in the absence of non-radiative effects, it is the lower limit of the experimental value, J₀), k is the Boltzmann constant, T is the temperature, and q is the elementary charge. The theory of detailed balance requires that in equilibrium, i.e. the open circuit condition, the photocurrent is balanced by an equal and opposite injection current, resulting in a total current of zero within the device. Previously, detailed balance has been invoked to relate ΔVₙᵣ to the forward-biased external emission efficiency. Other works have, incorrectly, assumed that the external emission efficiency is equal to the EL external quantum efficiency, η_{EL}, and asserted that in the radiative limit η_{EL}=1. For an organic device where emission is dominated by the CT state, however, the current resulting from non-radiative recombination will be exactly zero when the emissive CT state efficiency, η_{CT}, is unity, which is not equivalent to η_{EL}=1. For organics, CT state emission is confined to donor/acceptor junctions, thus η_{CT} can only account for non-radiative defect sites occurring within the active region. Rather, the measured EL efficiency is given by:

$${η}_{EL} = γ {χ}_{em} {η}_{CT} , \qquad ( 2 )$$

where γ is the charge balance factor (i.e. the ratio of photons emitted to electrons that radiatively recombine with holes at the HJ). The ratio of emissive CT states formed by electrical injection, χₑₘ, depends on whether the states reside in the singlet or triplet manifold. That is, if the CT states are singlets and the triplets are non-emissive, then χₑₘ=0.25. Alternatively, χₑₘ may assume a value as high as 1 if the CT states are emissive triplets or a mixed state. Thus, η_{EL} must account for χₑₘ, and γ when determining the magnitude of η_{CT}.

Under open-circuit conditions, the ideal diode equation for an OPV is written:

$${J}_{0} ( exp ( \frac{q {V}_{oc}}{nkT} ) - \frac{{k}_{PPd}}{{k}_{PPd , eq}} ) = - {J}_{ph} \qquad ( 3 )$$

where n is the ideality factor (which is well-defined only for purely diffusion, n=1, and mid-gap recombination, n=2, currents), k_{PPd} is the polaron pair dissociation rate at V_{oc}, k_{PPd,eq} is the polaron pair dissociation rate in thermal equilibrium, and Jₚₕ is the photocurrent. An OPV in thermal equilibrium requires that the photocurrent due to thermal excitation is balanced by current injection leading to recombination at the CT state. Thus, in the dark:

$${J}_{out} ( {V}_{oc} ) = {J}_{0}^{rad} ( exp ( \frac{q {V}_{oc}}{nkT} ) - 1 ) \approx {J}_{0}^{rad} ( exp ( \frac{q {V}_{oc}}{nkT} ) ) , \qquad ( 4 )$$

where J₀^{rad} is the saturation current due to excitation due to a room temperature blackbody, and Jₒᵤₜ is the radiative recombination current density generated from the CT state. For simplicity, we assume k_{PPd}≈k_{PPd,eq} in Eq. 4. Returning to η_{EL}, which is defined as the number of photons emitted per electrons injected:

$${η}_{EL} = \frac{{J}_{out} ( {V}_{oc} )}{{J}_{inj} ( {V}_{oc} )} γ {χ}_{em} \qquad ( 5 )$$

where Jᵢₙⱼ is the injected current density resulting from the applied forward voltage. Equation 2 provides a physical understanding for the origin of organic light-emitting diode (OLED) efficiency, while Eq. 5 is defined in terms of measurable quantities from the OPV cell operated as an OLED.

At open circuit, Jᵢₙⱼ(V_{oc}) must be balanced by an equal and opposite photocurrent, i.e. Jᵢₙⱼ(V_{oc})=Jₚₕ(V_{oc}); an equality that allows us to relate η_{EL} to V_{oc}. For OPVs, it cannot be assumed that Jₚₕ(V_{oc})=J_{sc}, because Jₚₕ is dependent on voltage. This results because, in an ideal junction, k_{PPd} is dependent on electric field at the heterojunction. Thus,

$${J}_{inj} ( {V}_{oc} ) = {J}_{ph} ( {V}_{oc} ) = {J}_{sc} - {J}_{Δ} \qquad ( 6 )$$

where J_{Δ} accounts for the difference between Jₚₕ(V_{oc}) and J_{sc}.

Hence the higher η_{EL} the lower is the loss in open circuit Voltage. For a highly efficient OPV device we would like η_{EL} to approach unity, so in this disclosure, material designs are employed where η_{EL} is greater than 5%, greater than 10%, greater than 20%, and greater than 50%.

### Example 2: Small Singlet-Triplet Gap Materials Based on Dipyrrin Derivatives

Initial investigations into small singlet—triplet gap (low ΔE_{ST}) materials began by examining porphyrins. Porphyrins are of interest because they are naturally occurring molecules that have high molar absorptivities (>10⁵ M⁻¹ cm⁻¹) and the ability to absorb low energy light due to their planar π—conjugated cores. The rigid structure of this core presents the added ability to control the placement of additional components, in this case donors and acceptors, that would allow for the modification of the structural and electronic properties of the molecule. One such property that may be controlled would be the singlet and triplet energies, which would then influence the absorption and emissive properties of the material.

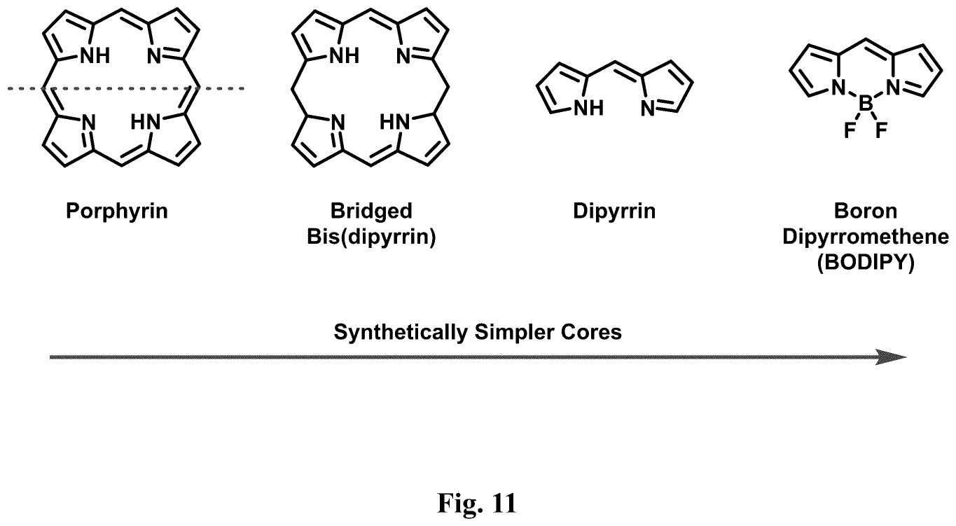

Seeking a more synthetically simple candidate that shared many of the same properties as a porphyrin, the structure was truncated down to a Dipyrrin structure (which resembles roughly half of a porphyrin, FIG. 11). This Dipyrrin motif is the backbone for a class of molecules called Boron Dipyrromethene (BODIPY), and these molecules are strongly absorbing, allow for rigid positioning of components, and are synthetically simple to produce.

A series of donor and acceptor groups are illustrated below, but a large range of donor and acceptor groups can be used to tune the excited state energy and singlet-triplet gaps.

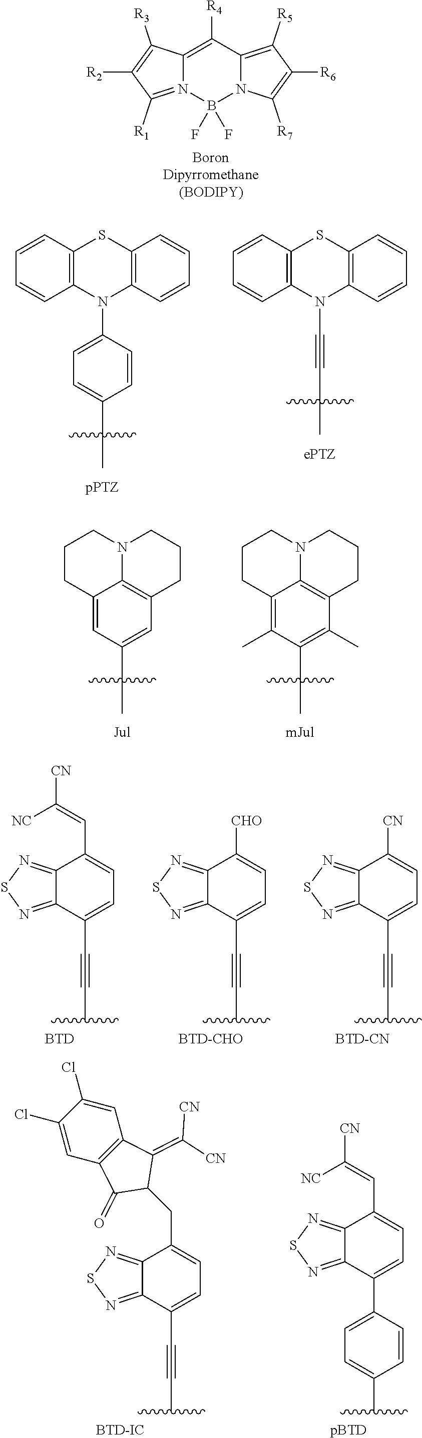

TABLE 1
Screened BODIPY structures and singlet and triplet energies and ΔE_{ST}.
Singlet, triplet, and energy difference are provided as electron volts (eV).

| Entry | R₁ | R₂ | R₃ | R₄ | R₅ | R₆ | R₇ | S¹ | T¹ | ΔE_{ST} |
|---|---|---|---|---|---|---|---|---|---|---|
| 1 | Me | H | Me | H | Me | H | Me | 3.031 | 1.461 | 1.570 |
| 2 | BTD | Me | Me | H | Me | Me | H | 2.017 | 1.063 | 0.953 |
| 3 | BTD | Me | Me | H | Me | Me | BTD | 1.577 | 0.845 | 0.733 |
| 4 | BTD | Me | Me | pPTZ | Me | Me | H | 1.460 | 1.061 | 0.399 |
| 5 | BTD | Me | Me | pPTZ | Me | Me | BTD | 1.169 | 0.860 | 0.309 |
| 6 | Me | BTD | Me | H | Me | H | Me | 2.085 | 1.276 | 0.809 |
| 7 | Me | BTD | Me | H | Me | BTD | Me | 1.923 | 1.270 | 0.654 |
| 8 | Me | BTD | Me | pPTZ | Me | H | Me | 1.573 | 1.282 | 0.291 |
| 9 | Me | BTD | Me | pPTZ | Me | BTD | Me | 1.349 | 1.282 | 0.067 |
| 10 | Me | BTD-CHO | Me | pPTZ | Me | BTD-CHO | Me | 1.604 | 1.456 | 0.149 |
| 11 | Me | BTD-CN | Me | pPTZ | Me | BTD-CN | Me | 1.572 | 1.448 | 0.124 |
| 12 | Me | pPTZ | Me | BTD | Me | pPTZ | Me | 0.736 | 0.735 | 0.001 |
| 13 | Me | ePTZ | Me | pBTD | Me | ePTZ | Me | 1.248 | 1.244 | 0.004 |
| 14 | Me | H | Me | JUL | Me | H | Me | 2.35 | 1.55 | 0.807 |
| 15 | Me | BTD | Me | JUL | Me | BTD | Me | 1.66 | 1.27 | 0.394 |
| 16 | H | BTD | H | JUL | H | BTD | H | 1.94 | 1.30 | 0.634 |
| 17 | Me | H | Me | mJUL | Me | H | Me | 2.16 | 1.56 | 0.600 |
| 18 | Me | BTD | Me | mJUL | Me | BTD | Me | 1.36 | 1.27 | 0.087 |
| 19 | H | BTD | H | mJUL | H | BTD | H | 1.33 | 1.21 | 0.113 |

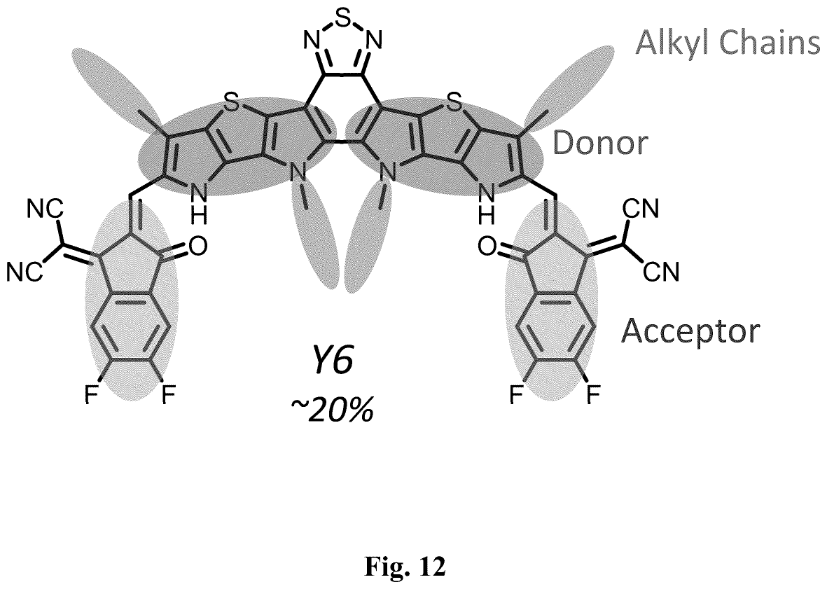

Based on previous studies with the compound Y6 (FIG. 12), further studies were performed using the BODIPY scaffold:

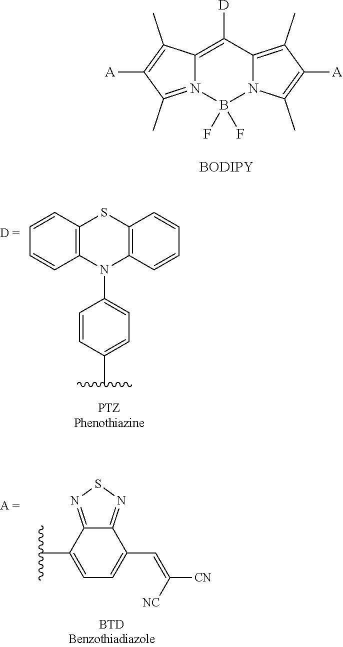

This D-BODIPY-A core has the following desirable features: large Molar Absorbance (of core); ideal positioning of D & A; a straight-forward/modular synthesis; and a predicted small ΔE_{S-T}

### Possible Variations are:

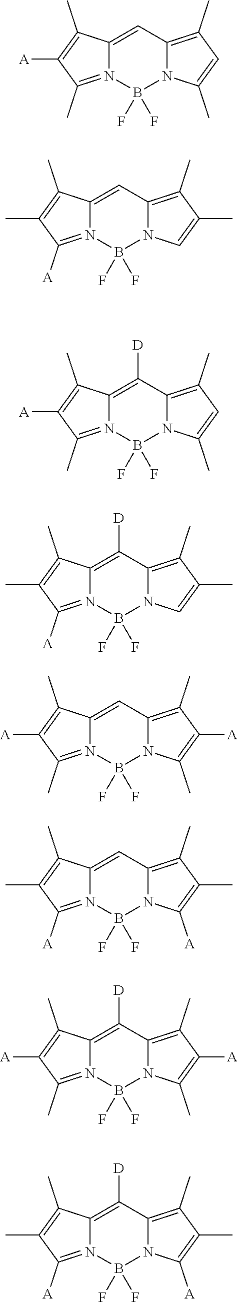

The following exemplary compound was identified:

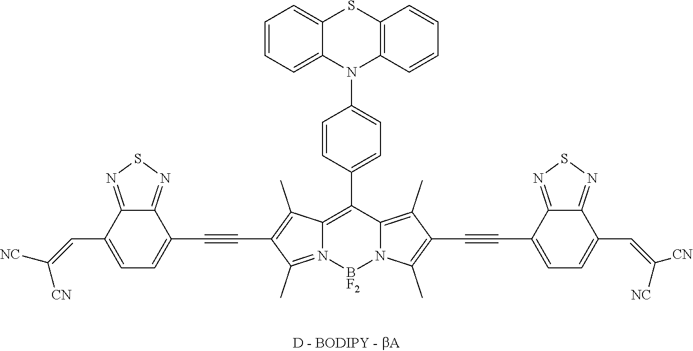

Calculated Values:

| HOMO (eV) | −5.41 | |
|---|---|---|
| LUMO (eV) | −3.79 | |
| GAP (eV) | −1.62 | (765 nm) |
| S₁ (eV) | 1.35 | (0.001) |
| T₁ (eV) | 1.28 | (0.001) |
| Sₙ (eV) | 1.94 | (1.995) |

| | |
|---|---|
| ΔE_{S-T} (eV) | 0.070 |

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. An organic photovoltaic device comprising:
an anode;
a cathode; and
a photoactive organic material in a layer disposed between the anode and the cathode,
wherein:
the energy difference between the triplet energy state (T₁) and the singlet energy state (S₁) (ΔE_{ST}) in the photoactive organic material is less than about 300 meV; and
when the organic photovoltaic device is illuminated with light having an AM1.5 spectrum, the organic photovoltaic device has an open circuit voltage of greater than 0.9 V and a power conversion efficiency of greater than 22%, and an EL external quantum efficiency >5%.

2. The organic photovoltaic device of claim 1, wherein the organic photovoltaic device is a tandem photovoltaic device comprising at least two subcells;
wherein at least one subcell is organic; and
at least one subcell is organic, perovskite, or CdTe.

3. (canceled)

4. The organic photovoltaic device of claim 1, wherein ΔE_{ST} in the photoactive organic material is less than about 200 meV.

5.-8. (canceled)

9. The organic photovoltaic device of claim 1, wherein the organic photovoltaic device has an EL external quantum efficiency >30%.

10.-12. (canceled)

13. The organic photovoltaic device of claim 1, wherein the organic photovoltaic device has an EL external quantum efficiency >50%.

14. The organic photovoltaic device of claim 1
wherein the photoactive organic material comprises a compound of General Formula (I): 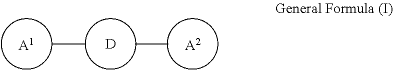
wherein:
D is a donor; and
A¹ and A² are each independently an acceptor.

15.-18. (canceled)

19. The organic photovoltaic device of claim 14, wherein the compound has a HOMO/LUMO overlap of greater than 10%.

20. The organic photovoltaic device of claim 14, wherein the organic photovoltaic device further comprises a compound comprising one of the following general formulae: 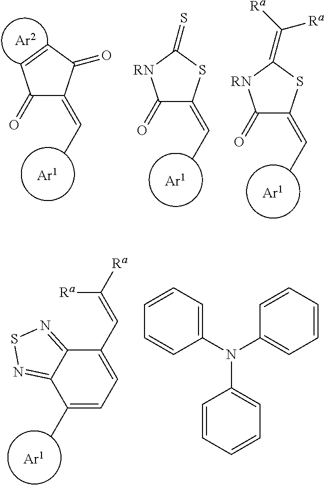
wherein
Ar¹ and Ar² are each independently selected from C₅-C₁₆ aryl and C₂-C₁₆ heteroaryl; and
R^{a} is an electron withdrawing group.

21. The organic photovoltaic device of claim 1, wherein the photoactive organic material comprises a compound of General Formula (I): 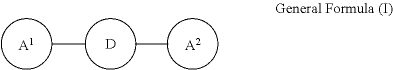
wherein:
D is a donor;
A¹ and A² are each independently a compound capable of thermally assisted delayed fluorescence (TADF); and
A¹ and A² are each covalently bound to D.

22. The organic photovoltaic device of claim 1, wherein the photoactive organic material comprises a compound of General Formula (I): 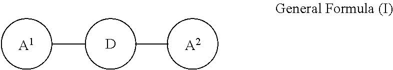
wherein:
D is a donor;
A¹ and A² are each independently an acceptor; and
D is a compound capable of thermally assisted delayed fluorescence (TADF).

23. The organic photovoltaic device of claim 1, wherein the photoactive organic material comprises a compound of General Formula (I): 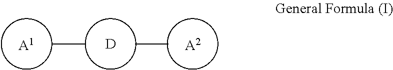
wherein:
D is a donor;
A¹ and A² are each independently an acceptor; and
the oscillator strength for the transition from the ground state and the lowest energy excited state is at least 0.1.

24. The organic photovoltaic device of claim 1, wherein the photoactive organic material comprises a compound of General Formula (I): 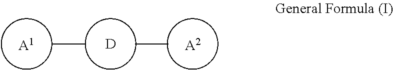
wherein:
D is a donor;
A¹ and A² are each independently an acceptor; and
the energy difference between the triplet energy state (T₁) and the singlet energy state (S₁) (ΔE_{ST}) is less than about 200 meV.

25. The organic photovoltaic device of claim 1, wherein the photoactive organic material comprises a compound represented by General Formula (I): 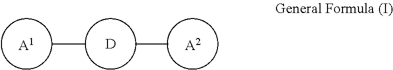
wherein:
D is a donor; and
A¹ and A² are each independently an acceptor; and
the energy difference between the triplet energy state (T₁) and the singlet energy state (S₁) (ΔE_{ST}) is less than about 100 meV.

26. The compound of claim 25, wherein D comprises a group represented by a formula selected from the group consisting of Formula (D-1) to Formula (D-5): 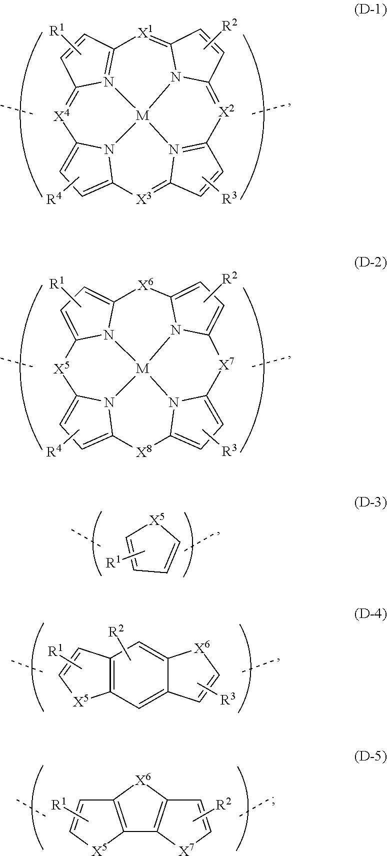
wherein
the dashed lines indicate direct bonds to A¹ and A²;
M is a monovalent, divalent, trivalent, or tetravalent atom;
each R¹ to R⁴ independently represents mono to the maximum allowable substitution;
each R¹ to R⁴ independently represents hydrogen or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof;
any two adjacent R¹ to R⁴ are optionally joined or fused together to form a ring which is optionally substituted;
each X¹ to X⁴ independently represents CR or N;
each X⁵ to X⁷ independently represents CR₂, NR, O, or S; and
each R is independently an electron donating group, hydrogen, or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof.

27. The compound of claim 25, wherein D comprises a structure selected from the group consisting of: 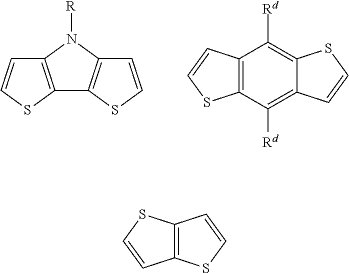
wherein
R is selected from the group consisting of an electron donating group, hydrogen, or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof; and
each R^{d} is independently an electron donating group.

28. The compound of claim 25, wherein D comprises a structure represented by Formula (D-6): 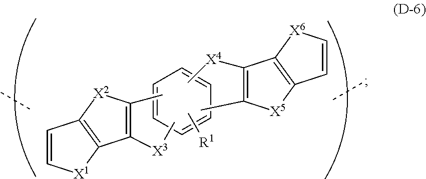
wherein
the dashed lines indicate direct bonds to A¹ and A²;
each X¹ to X⁴ independently represents O, S, NR, and CR₂;
R¹ represents mono to the maximum allowable substitution;
each R is independently hydrogen or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof; and
each occurrence of R¹ is independently selected from the group consisting of an electron donating group, hydrogen, or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof.

29. The compound of claim 25, wherein D is represented by a structure selected from the group consisting of: 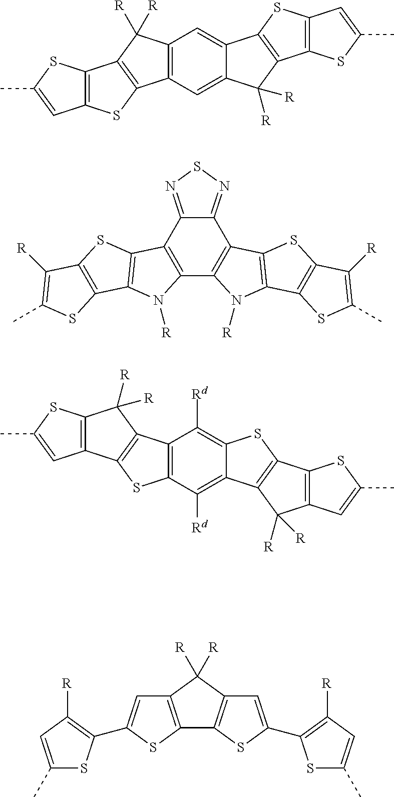
wherein
each R independently represents hydrogen or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof;
each R^{d} independently represents an electron donating group; and
the dashed lines indicate direct bonds to A¹ and A².

30. (canceled)

31. The compound of claim 25, wherein A¹ and A² each independently comprise a group represented by a formula selected from the group consisting of Formula (A-1) to Formula (A-7): 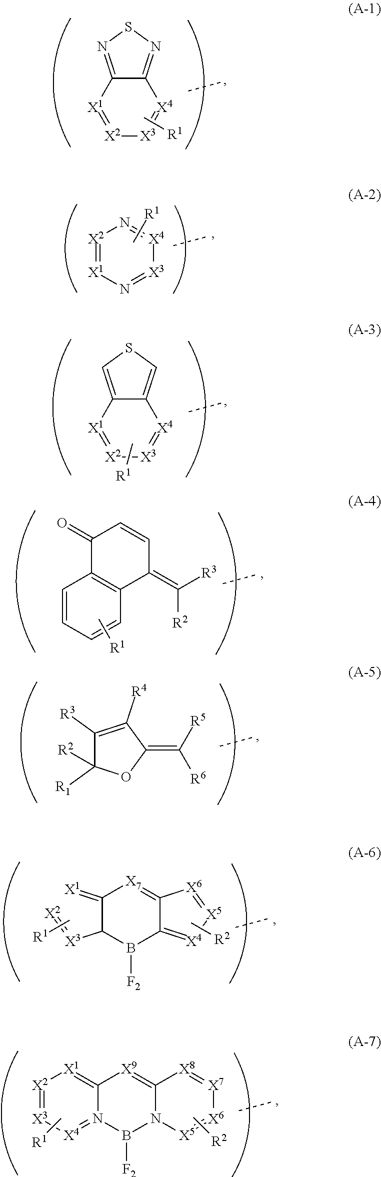
wherein
the dashed line indicates the direct bond to D;
each R¹ to R⁶ independently represents mono to the maximum allowable substitution;
each R¹ to R⁶ independently represents hydrogen or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof;
wherein any two adjacent R¹ to R⁶ are optionally joined or fused together to form a ring which is optionally substituted;
each X¹ to X⁹ independently represents CR or N; and
each R is independently an electron withdrawing group, hydrogen, or a substituent selected from the group consisting of deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitrile, isonitrile, sulfanyl, boryl, acyl, carboxylic acid, benzoyl, ether, ester, vinyl, ketone, sulfinyl, sulfonyl, cyano, phosphino and combinations thereof.

32. The compound of claim 25, wherein A¹ and A² are each independently selected from the group consisting of 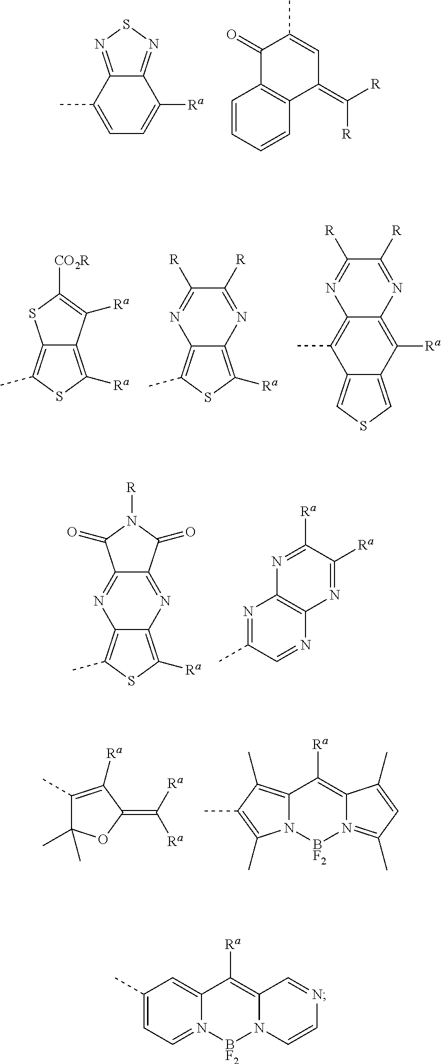
wherein
the dashed line indicates a direct bond to D;
each R is independently selected from the group consisting of hydrogen or a substituent selected from the group consisting of deuterium, C₁-C₂₀ alkyl, C₁-C₂₀ heteroalkyl, C₅-C₁₆ aryl, C₂-C₁₆ heteroaryl, C₅-C₁₆ cycloalkyl;
each R^{a} is independently an electron withdrawing group; and
wherein any two adjacent R or R^{a} may optionally join to form a ring.

33. (canceled)

34. The compound of claim 25, wherein the dihedral angle between best least squares planes of the D group and the least square planes of A¹ or A² is greater than about 30°.
